(19) United States
(12) Patent Application Publication
(10) Pub. No.: US 2026/0282511 A1
(43) Pub. Date: Sep. 17, 2026

(54) SELF-ALIGNING GATE STRUCTURE PATTERNING IN STACKING TRANSISTORS AND STRUCTURES RESULTING THEREFROM

(71) Applicant: Taiwan Semiconductor Manufacturing Co., Ltd., Hsinchu (TW)

(72) Inventors: Kai-Chieh Yang, New Taipei (TW); Szu-Hua Chen, Tainan (TW); Wei-Yen Woon, Taoyuan (TW); Szuya Liao, Zhubei (TW)

(21) Appl. No.: 19/268,255

(22) Filed: Jul. 14, 2025

Related U.S. Application Data
(60) Provisional application No. 63/770,022, filed on Mar. 11, 2025.

(51) Int. Cl. H10D 84/01; H10D 84/85

(52) U.S. Cl. CPC H10D 84/0181; H10D 84/0167; H10D 84/017; H10D 84/0188; H10D 84/851; H10D 84/856

(57) ABSTRACT

A method includes forming a fin over a substrate, the fin comprising lower nanostructures, upper nanostructures, dummy nanostructures, and the dielectric isolation layer disposed between the lower nanostructures and the upper nanostructures; forming a source/drain region adjacent to the fin; forming a recess laterally adjacent to the fin; removing the dummy nanostructures from the fin; forming gate dielectrics around the lower nanostructures and the upper nanostructures; dispensing a directed self-assembly (DSA) material into the recess; exposing the DSA material to a selected ambient, polymer molecules of the DSA material being substantially aligned in the recess; performing a curing process on a lower portion of the DSA material; performing a first etch process to remove an uncured upper portion of the DSA material; doping a dipole dopant into the upper gate dielectrics; and forming a gate electrode around the lower nanostructures and the upper nanostructures.

### PRIORITY CLAIM AND CROSS-REFERENCE

This application claims the benefit of the following provisionally filed U.S. patent application: Application No. 63/770,022, filed on Mar. 11, 2025, and entitled “METHOD FOR MANUFACTURING SEMICONDUCTOR STRUCTURE,” which application is hereby incorporated herein by reference.

### BACKGROUND

Semiconductor devices are used in a variety of electronic applications such as personal computers, cell phones, digital cameras, and other electronic equipment. Semiconductor devices are typically fabricated by sequentially depositing insulating or dielectric layers, conductive layers, and semiconductor layers over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. As the semiconductor industry further progresses towards increased device density, higher performance, and lower costs, challenges from both fabrication and design have led to stacked device configurations, such as stacking transistors, which include complementary field effect transistors (CFETs). As the minimum feature sizes are reduced, however, additional features are introduced.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a perspective view of an example stacking transistor, in accordance with some embodiments.

FIGS. 2, 3A, 3B, 4A, 4B, 5A, 5B, 5C, 5D, 6A, 6B, 7A, 7B, 8A, 8B, 9A, 9B, 10A, 10B, 11A, 11B, 12A, 12B, 13A, 13B, 13C, 13D, 14A, 14B, 14C, and 14D are views of intermediate stages in the manufacturing of stacking transistors, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A stacking transistor structure including an upper transistor and a lower transistor that are vertically stacked and the method of forming the same are provided. After forming source/drain regions of the lower transistor and the upper transistor adjacent to lower and upper channel regions, a gate replacement process is performed to form a gate stack comprising gate dielectrics, a lower gate electrode, and an upper gate electrode. For example, a dummy gate structure and dummy material are removed to form a recess comprising a trench region between adjacent fins and gap regions between adjacent nanostructures. The gate dielectrics are formed over and around lower and upper nanostructures (e.g., lower and upper channel regions) in lower and upper parts of the recess, respectively. A directed self-assembly (DSA) material is used to form a dummy fill material which streamlines patterning for process steps performed for either the upper transistor or the lower transistor. For example, the DSA material includes block copolymers which will align in the trench to assemble the DSA material into two distinct material layers (e.g., lower and upper). Following a treatment, the upper material layer may be etched or washed away while the lower material layer remains as the dummy fill material. In some embodiments, a dipole film may then be formed around exposed portions of the gate dielectrics (e.g., upper gate dielectrics) around the upper nanostructures. A dipole dopant process is performed to drive or diffuse dopants from the dipole film into the upper gate dielectrics. As a result, the doped upper gate dielectrics are tuned to the conductivity type of the upper transistor. The lower and upper gate electrodes are then formed sequentially or in parallel. The resulting stacking transistors may be fabricated at a higher yield through a simplified process, and function with improved performance and reliability.

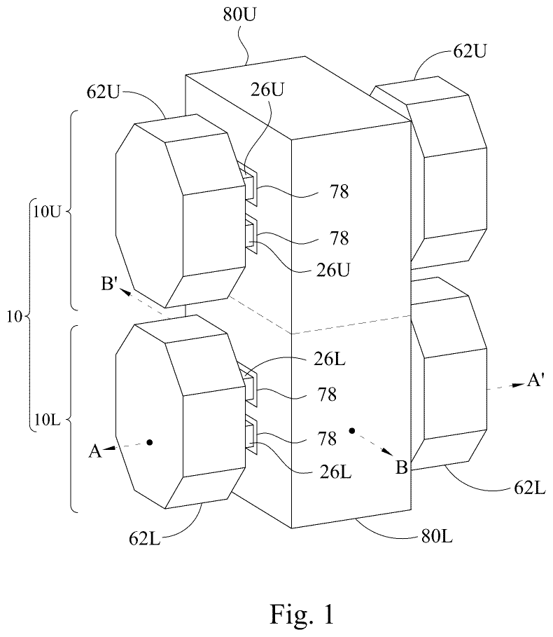

FIG. 1 illustrates an example of a stacking transistor 10 (including FETs (transistors) 10U and 10L) in accordance with some embodiments. FIG. 1 is a three-dimensional view, and some features of the stacking transistor are omitted for illustration clarity.

The stacking transistor includes multiple vertically stacked FETs. For example, a stacking transistor may include a lower nanostructure-FET 10L of a first device type (e.g., n-type/p-type) and an upper nanostructure-FET 10U of a second device type (e.g., p-type/n-type). When the stacking transistor is a CFET, the second device type of the upper nanostructure-FET 10U is opposite to the first device type of the lower nanostructure-FET 10L. The nanostructure-FETs 10U and 10L include semiconductor nanostructures 26 (including lower semiconductor nanostructures 26L and upper semiconductor nanostructures 26U), where the semiconductor nanostructures 26 act as the channel regions for the nanostructure-FETs. The lower semiconductor nanostructures 26L are for the lower nanostructure-FET 10L, and the upper semiconductor nanostructures 26U are for the upper nanostructure-FET 10U. In other embodiments, the stacking transistors may be applied to other types of transistors (e.g., finFETs, or the like) as well.

Gate dielectrics 78 encircle the respective semiconductor nanostructures 26. Gate electrodes 80 (including a lower gate electrode 80L and an upper gate electrode 80U) are over the gate dielectrics 78. Source/drain regions 62 (including lower source/drain regions 62L and upper source/drain regions 62U) are disposed on opposing sides of the gate dielectrics 78 and the respective gate electrodes 80. Each of the source/drain regions 62 may refer to a source or a drain, individually or collectively dependent upon the context. Isolation features (not shown) may be formed to separate desired ones of the source/drain regions 62 and/or desired ones of the gate electrodes 80.

FIG. 1 further illustrates reference cross-sections that are used in later figures. Cross-section A-A′ is a vertical cross-section that is parallel to a longitudinal axis of the semiconductor nanostructures 26 of a stacking transistor and in a direction of, for example, a current flow between the source/drain regions 62 of the stacking transistor. Cross-section B-B′ is a vertical cross-section that is perpendicular to cross-section A-A′ and along a longitudinal axis of a gate electrode 80 of the CFET. Subsequent figures may refer to these reference cross-sections for clarity.

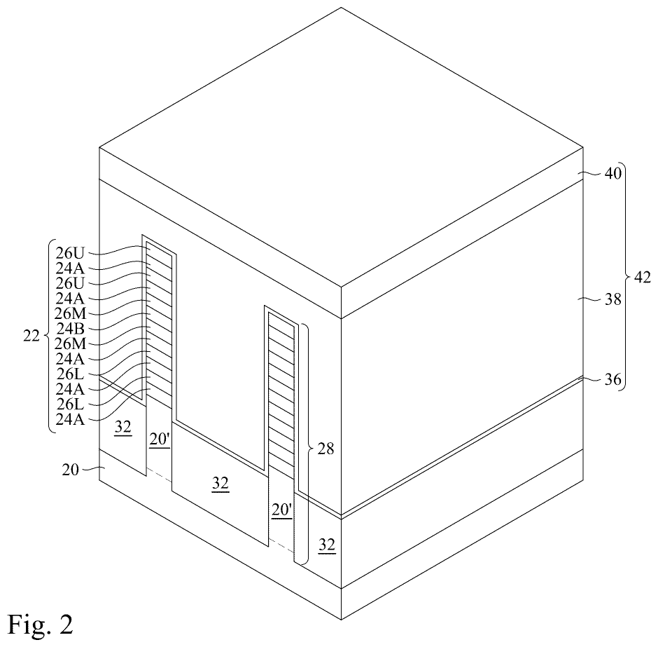

FIGS. 2 through 14D illustrate the cross-sectional views of intermediate stages in the formation of stacking transistors (as schematically represented in FIG. 1) in accordance with some embodiments. In subsequent discussion, unless specified otherwise, the figures having digits followed by letter “A” or letter “C” illustrate the vertical cross-sectional views along a similar cross-section as vertical reference cross-section A-A′ in FIG. 1. The figures having digits followed by letter “B” or letter “D” illustrate the vertical cross-sectional views along a similar cross-section as the vertical reference cross-section B-B′ in FIG. 1. Moreover, for the sake of example, figures with the reference cross-section A-A′ may be depicted through device region 100A of corresponding figures with the reference cross-section B-B′, unless otherwise stated or depicted.

In FIG. 2, a wafer, which includes substrate 20, is provided. Substrate 20 may be a semiconductor substrate, such as a bulk semiconductor, which may be doped (e.g., with a p-type or an n-type dopant) or undoped. Other substrates, such as a multi-layered or gradient substrate may also be used. In some embodiments, the semiconductor material of the substrate 20 may include silicon, germanium, carbon-doped silicon, a III-V compound semiconductor; or the like, or combinations thereof.

Semiconductor strips 28 are formed extending upwards from the semiconductor substrate 20. Each of semiconductor strips 28 includes semiconductor strip 20′ (patterned portions of the semiconductor substrate 20, also referred to as semiconductor fins 20′) and a multi-layer stack 22. Note that the semiconductor strips 28 may also be referred to as semiconductor fins. The stacked components of the multi-layer stack 22 are referred to as nanostructures hereinafter. Specifically, the multi-layer stack 22 includes dummy nanostructures 24A, one or more dummy nanostructures 24B, lower semiconductor nanostructures 26L, and upper semiconductor nanostructures 26U. The dummy nanostructures 24A and the dummy nanostructures 24B may further be collectively referred to as dummy nanostructures 24, and the lower semiconductor nanostructures 26L and the upper semiconductor nanostructures 26U may further be collectively referred to as semiconductor nanostructures 26.

The dummy nanostructures 24A are formed of a first semiconductor material, and the dummy nanostructures 24B are formed of a second semiconductor material different from the first semiconductor material. The first and second semiconductor materials may be selected from the candidate semiconductor materials of the substrate 20. The first and second semiconductor materials have a high etching selectivity to one another. As such, the dummy nanostructures 24B may be removed at a faster rate than the dummy nanostructures 24A in subsequent processes.

The semiconductor nanostructures 26 (including the lower semiconductor nanostructures 26L and upper semiconductor nanostructures 26U) are formed of one or more third semiconductor material(s). The third semiconductor material(s) may be selected from the candidate semiconductor materials of the substrate 20. The lower semiconductor nanostructures 26L and the upper semiconductor nanostructures 26U may be formed of the same semiconductor material, or may be formed of different semiconductor materials. Further, the first and second semiconductor materials of the dummy nanostructures 24 have a high etching selectivity to the third semiconductor material(s) of the semiconductor nanostructures 26. As such, the dummy nanostructures 24 may be selectively removed in subsequent process steps without significantly removing the semiconductor nanostructures 26. In some embodiments, the dummy nanostructures 24A are formed of or comprise silicon germanium, the semiconductor nanostructures 26 are formed of silicon, and the dummy nanostructures 24B may be formed of germanium or silicon germanium with a higher germanium atomic percentage than the dummy nanostructures 24A.

The lower semiconductor nanostructures 26L will provide channel regions for lower nanostructure-FETs of the CFETs. The upper semiconductor nanostructures 26U will provide channel regions for upper nanostructure-FETs of the CFETs. The semiconductor nanostructures 26 may include middle semiconductor nanostructures 26M, such as an upper semiconductor nanostructure 26U and a lower semiconductor nanostructure 26L, that are immediately above/below (e.g., in contact with) the dummy nanostructures 24B may be used for isolation and may or may not act as channel regions for the CFETs. The dummy nanostructures 24B will be subsequently replaced with isolation structures that define boundaries of the lower nanostructure-FETs and the upper nanostructure-FETs.

To form the semiconductor strips 28, layers of the first, second, and third semiconductor materials (arranged as illustrated and described above) may be deposited over the semiconductor substrate 20. The layers of the first, second, and third semiconductor materials may be grown by a process such as Vapor Phase Epitaxy (VPE) or Molecular Beam Epitaxy (MBE), deposited by a process such as Chemical Vapor Deposition (CVD) process or an Atomic Layer deposition (ALD) process, or the like. Then, a patterning process may be applied to the layers of the first, second, and third semiconductor materials as well as the semiconductor substrate 20 to define the semiconductor strips 28, which includes the semiconductor strips 20′, the dummy nanostructures 24, and the semiconductor nanostructures 26.

The semiconductor fins and the nanostructures may be patterned by any suitable method. For example, the patterning process may include one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used as an etching mask for the patterning process to etch the layers of the first, second, and third semiconductor materials and the semiconductor substrate 20. The etching may be performed by any acceptable etch process, such as a Reactive Ion Etch (RIE), Neutral Beam Etch (NBE), the like, or a combination thereof. The etching may be anisotropic.

As also illustrated by FIG. 2, isolation regions 32 (e.g., isolation features) such as shallow trench isolation (STI) regions 32 are formed over the substrate 20 and between adjacent semiconductor strips 28. STI regions 32 may include a dielectric liner and a dielectric material over the dielectric liner. Each of the dielectric liner and the dielectric material may include an oxide such as silicon oxide, a nitride, such as silicon nitride, the like, or a combination thereof. The formation of the STI regions 32 may include depositing the dielectric layer(s), and performing a planarization process such as a Chemical Mechanical Polish (CMP) process, a mechanical polishing process, or the like to remove excess portions of the dielectric materials. The deposition processes may include ALD, High-Density Plasma CVD (HDP-CVD), Flowable CVD (FCVD), the like, or a combination thereof. In some embodiments, the STI regions 32 include silicon oxide formed by an FCVD process, followed by an anneal process. Then, the dielectric layers(s) are recessed to define the STI regions 32. The dielectric layer(s) maybe recessed such that upper portions of semiconductor strips 28 (including multi-layer stacks 22) protrude higher than the remaining STI regions 32.

After the STI regions 32 are formed, dummy gate stacks 42 may be formed over and along sidewalls of the upper portions of the semiconductor strips 28 (the portions that protrude higher than the STI regions 32). Forming the dummy gate stacks 42 may include forming dummy dielectric layer 36 on the semiconductor strips 28. The dummy dielectric layer 36 may be formed of or comprise, for example, silicon oxide, silicon nitride, a combination thereof, or the like, and may be deposited or thermally grown according to acceptable techniques. A dummy gate layer 38 is formed over the dummy dielectric layer 36. The dummy gate layer 38 may be deposited, for example, through Physical Vapor Deposition (PVD), CVD, or other techniques, and then planarized, such as by a CMP process. The material of dummy gate layer 38 may be conductive or non-conductive, and may be selected from a group including amorphous silicon, polycrystalline-silicon (polysilicon), poly-crystalline silicon-germanium (poly-SiGe), or the like. A mask layer 40 is formed over the planarized dummy gate layer 38, and may include, for example, silicon nitride, silicon oxynitride, or the like. Next, the mask layer 40 may be patterned through photolithography and etching processes to form a mask, which is then used to etch and pattern dummy gate layer 38, and possibly the dummy dielectric layer 36. The remaining portions of mask layer 40, dummy gate layer 38, and dummy dielectric layer 36 form dummy gate stacks 42.

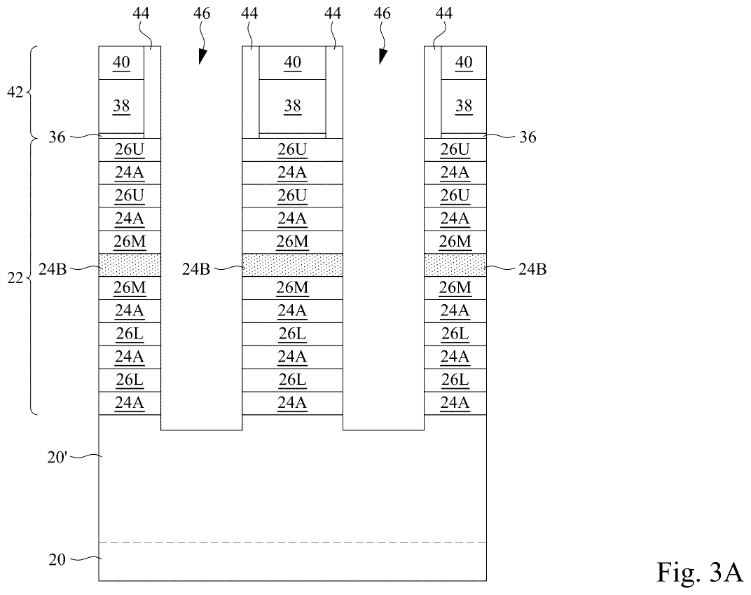

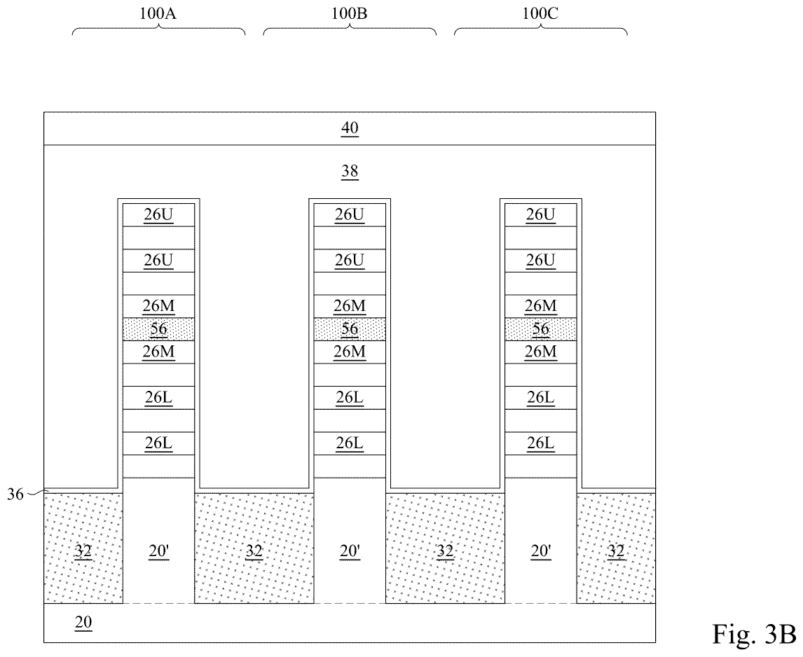

In FIGS. 3A and 3B, gate spacers 44 and source/drain recesses 46 are formed. First, the gate spacers 44 are formed over the multi-layer stacks 22 and on exposed sidewalls of dummy gate stacks 42. The gate spacers 44 may be formed by conformally forming one or more dielectric layers and subsequently etching the dielectric layers anisotropically. The applicable dielectric materials may include silicon oxide, silicon nitride, silicon oxynitride, silicon oxycarbonitride, or the like, which may be formed by a deposition process such as CVD, ALD, or the like.

Subsequently, source/drain recesses 46 are formed in semiconductor strips 28. The source/drain recesses 46 are formed through etching, and may extend through the multi-layer stacks 22 and into the semiconductor strips 20′. Bottom surfaces of the source/drain recesses 46 may be at a level above, below, or level with the top surfaces of the isolation regions 32. In the etching processes, the gate spacers 44 and the dummy gate stacks 42 mask some portions of the semiconductor strips 28. The etching may include a single etch process or multiple etch processes. Timed etch processes may be used to stop the etching of the source/drain recesses 46 upon the source/drain recesses 46 reaching a desired depth.

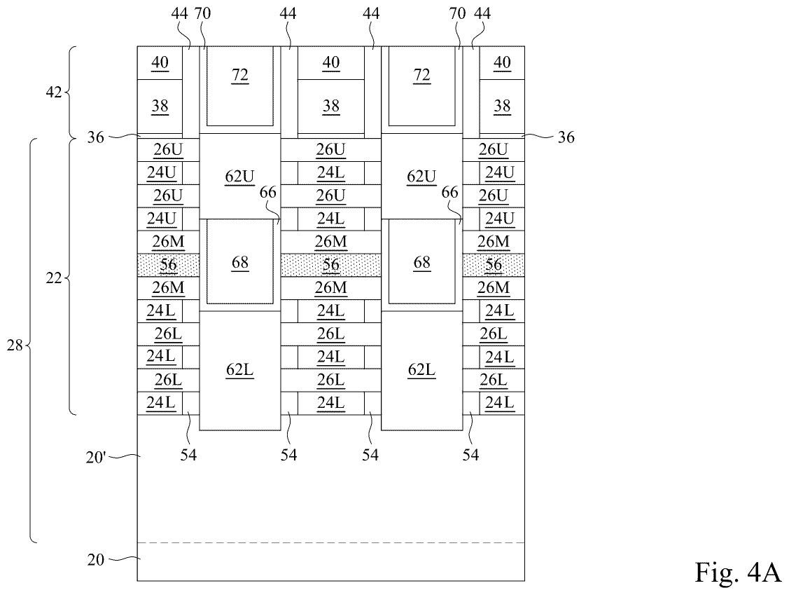

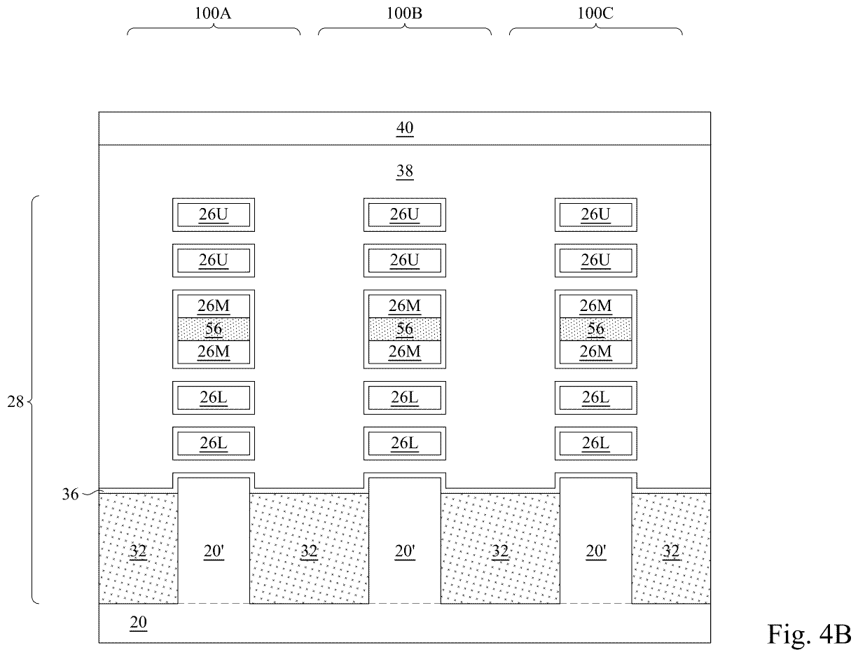

In FIGS. 4A and 4B, inner spacers 54 and dielectric isolation layers 56 are formed. Forming the inner spacers 54 and the dielectric isolation layers 56 may include an etching process that laterally etches the dummy nanostructures 24A and removes the dummy nanostructures 24B. The etching process may be isotropic and may be selective to the material of the dummy nanostructures 24, so that the dummy nanostructures 24 are etched at a faster rate than the semiconductor nanostructures 26. The etching process may also be selective to the material of the dummy nanostructures 24B, so that the dummy nanostructures 24B are etched at a faster rate than the dummy nanostructures 24A. In this manner, the dummy nanostructures 24B may be completely removed from between the lower semiconductor nanostructures 26L (collectively) and the upper semiconductor nanostructures 26U (collectively) without completely removing the dummy nanostructures 24A.

In some embodiments where the dummy nanostructures 24B are formed of germanium or silicon germanium with a high germanium atomic percentage, the dummy nanostructures 24A are formed of silicon germanium with a low germanium atomic percentage, and the semiconductor nanostructures 26 are formed of silicon free from germanium, the etch process may comprise a dry etch process using chlorine gas, with or without a plasma. Because the dummy gate stacks 42 wrap around sidewalls of the semiconductor nanostructures 26 (see FIG. 2), the dummy gate stacks 42 may support the upper semiconductor nanostructures 26U so that the upper semiconductor nanostructures 26U do not collapse upon removal of the dummy nanostructures 24B. Further, although sidewalls of the dummy nanostructures 24A are illustrated as being straight after the etching, the sidewalls may be concave or convex.

The inner spacers 54 are formed on sidewalls of the recessed dummy nanostructures 24A, and dielectric isolation layers 56 are formed between the upper semiconductor nanostructures 26U (collectively) and the lower semiconductor nanostructures 26L (collectively). As subsequently described in greater detail, source/drain regions will be subsequently formed in the source/drain recesses 46, and the dummy nanostructures 24A will be replaced with corresponding gate structures. The inner spacers 54 act as isolation features between the subsequently formed source/drain regions and the subsequently formed gate structures. Further, the inner spacers 54 may be used to prevent damage to the subsequently formed source/drain regions by subsequent etch processes, such as the etch processes used to form gate structures. The dielectric isolation layers 56, on the other hand, are used to isolate the upper semiconductor nanostructures 26U (collectively) from the lower semiconductor nanostructures 26L (collectively). Further, middle semiconductor nanostructures (ones of the semiconductor nanostructures 26 in contact with the dielectric isolation layers 56) and the dielectric isolation layers 56 may define the boundaries of the lower nanostructure-FETs and the upper nanostructure-FETs. Note that the dielectric isolation layers 56 may also be referred to as dielectric nanostructures, isolation nanostructures, dielectric isolation sheets, or variants thereof.

The inner spacers 54 and the dielectric isolation layers 56 may be formed by conformally depositing an insulating material in the source/drain recesses 46, on sidewalls of the dummy nanostructures 24, and between the upper and lower semiconductor nanostructures 26U and 26L, and then etching the insulating material. The insulating material may be a hard dielectric material, such as a carbon-containing dielectric material, such as silicon oxycarbonitride, silicon oxycarbide, silicon oxynitride, or the like. Other low-dielectric constant (low-k) materials having a k-value less than about 3.5 may be utilized. The insulating material may be formed by a deposition process, such as ALD, CVD, or the like. The etching of the insulating material may be anisotropic or isotropic. The insulating material, when etched, has portions remaining in the sidewalls of the dummy nanostructures 26A (thus forming the inner spacers 54) and has portions remaining in between the upper and lower semiconductor nanostructures 26U and 26L (thus forming the dielectric isolation layers 56).

As further illustrated by FIGS. 4A and 4B, lower and upper epitaxial source/drain regions 62L and 62U are formed. The lower epitaxial source/drain regions 62L are formed in the lower portions of the source/drain recesses 46. The lower epitaxial source/drain regions 62L are in contact with the lower semiconductor nanostructures 26L and are not in contact with the upper semiconductor nanostructures 26U. The inner spacers 54 electrically insulate the lower epitaxial source/drain regions 62L from the dummy nanostructures 24A, which will be replaced with replacement gates in subsequent processes.

The lower epitaxial source/drain regions 62L are epitaxially grown, and have a conductivity type that is suitable for the device type (p-type or n-type) of the lower nanostructure-FETs. When lower epitaxial source/drain regions 62L are n-type source/drain regions, the respective material may include silicon or carbon-doped silicon, which is doped with an n-type dopant such as phosphorous, arsenic, or the like. When lower epitaxial source/drain regions 62L are p-type source/drain regions, the respective material may include silicon or silicon germanium, which is doped with a p-type dopant such as boron, indium, or the like. The lower epitaxial source/drain regions 62L may be in-situ doped, and may be, or may not be, implanted with the corresponding p-type or n-type dopants. During the epitaxy of the lower epitaxial source/drain regions 62L, exposed surfaces of the upper semiconductor nanostructures 26U (e.g., sidewalls) may be masked to prevent undesired epitaxial growth on the upper semiconductor nanostructures 26U. After the lower epitaxial source/drain regions 62L are grown, the masks on the upper semiconductor nanostructures 26U may then be removed.

As a result of the epitaxy processes used for forming the lower epitaxial source/drain regions 62L, upper surfaces of the lower epitaxial source/drain regions 62L have facets which expand laterally outward beyond sidewalls of the multi-layer stacks 22. In some embodiments, adjacent lower epitaxial source/drain regions 62L remain separated after the epitaxy process is completed. In other embodiments, these facets cause neighboring lower epitaxial source/drain regions 62L of a same FET to merge.

A first contact etch stop layer (CESL) 66 and a first ILD 68 are formed over the lower epitaxial source/drain regions 62L. The first CESL 66 may be formed of a dielectric material having a high etching selectivity from the etching of the first ILD 68, such as silicon nitride, silicon oxide, silicon oxynitride, or the like, which may be formed by any suitable deposition process, such as CVD, ALD, or the like. The first ILD 68 may be formed of a dielectric material, which may be deposited by any suitable method, such as CVD, plasma-enhanced CVD (PECVD), or FCVD. The applicable dielectric material of the first ILD 68 may include phospho-silicate glass (PSG), boro-silicate glass (BSG), boron-doped phospho-silicate glass (BPSG), undoped silicate glass (USG), silicon oxide, or the like.

The formation processes may include depositing a conformal CESL layer, depositing a material for the first ILD 68, followed by a planarization process and then an etch-back process. In some embodiments, the first ILD 68 is etched first, leaving the first CESL 66 unetched. An anisotropic etching process is then performed to remove the portions of the first CESL 66 higher than the recessed first ILD 68. After the recessing, the sidewalls of the upper semiconductor nanostructures 26U are exposed.

Upper epitaxial source/drain regions 62U are then formed in the upper portions of the source/drain recesses 46. The upper epitaxial source/drain regions 62U may be epitaxially grown from exposed surfaces of the upper semiconductor nanostructures 26U. The materials of upper epitaxial source/drain regions 62U may be selected from the same candidate group of materials for forming lower source/drain regions 62L, depending on the desired conductivity type of upper epitaxial source/drain regions 62U. The conductivity type of the upper epitaxial source/drain regions 62U may be opposite the conductivity type of the lower epitaxial source/drain regions 62L in embodiments where the stacking transistors are CFETs. For example, the upper epitaxial source/drain regions 62U may be oppositely doped from the lower epitaxial source/drain regions 62L. Alternatively, the conductivity types of the upper epitaxial source/drain regions 62U and the lower epitaxial source/drain regions 62L may be the same. The upper epitaxial source/drain regions 62U may be in-situ doped, and/or may be implanted, with an n-type or p-type dopant. Adjacent upper source/drain regions 62U may remain separated after the epitaxy process or may be merged.

After the epitaxial source/drain regions 62U are formed, a second CESL 70 and a second ILD 72 are formed. The materials and the formation methods may be similar to the materials and the formation methods of first CESL 66 and first ILD 68, respectively, and are not discussed in detail herein. The formation process may include depositing the layers for CESL 70 and ILD 72, and performing a planarization process to remove the excess portion of the corresponding layers. After the planarization process, top surfaces of the second ILD 72, the gate spacers 44, and the masks 40 (if present) or the dummy gates 38 are substantially coplanar (within process variations). Accordingly, the top surfaces of the masks 40 (if present) or the dummy gates 38 are exposed through the second ILD 124. In the illustrated embodiment, the masks 40 remain after the removal process. In other embodiments, the masks 40 are removed such that the top surfaces of the dummy gates 38 are exposed through the first ILD 68.

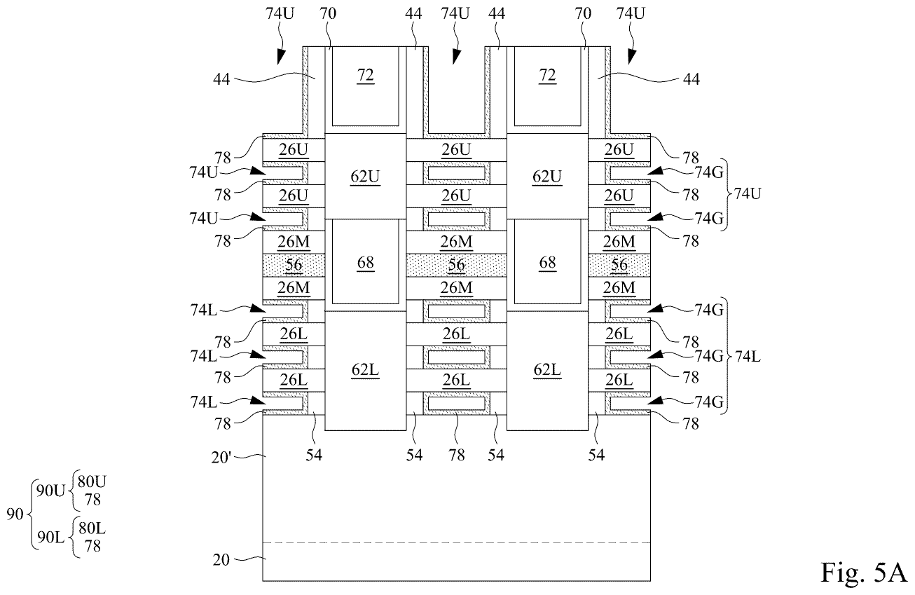

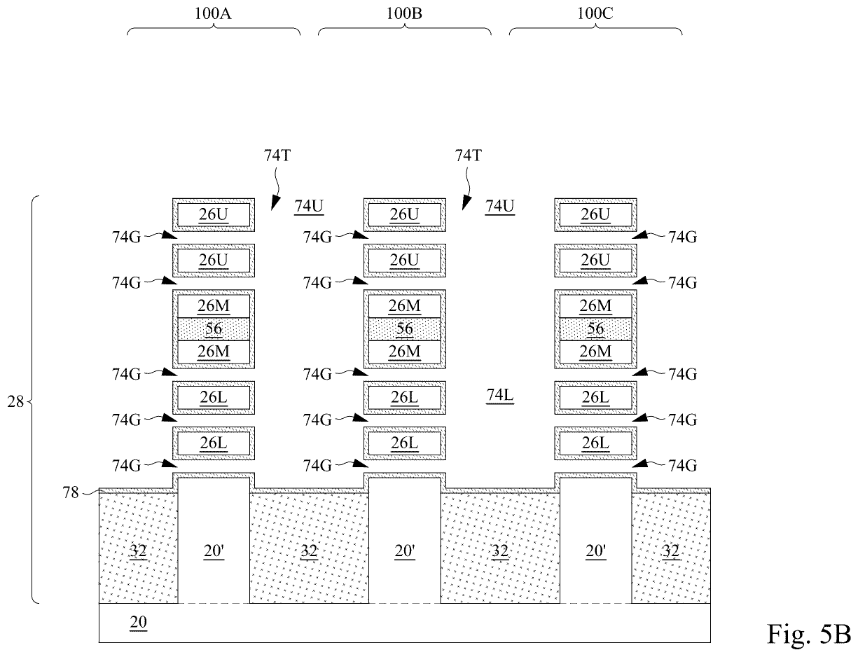

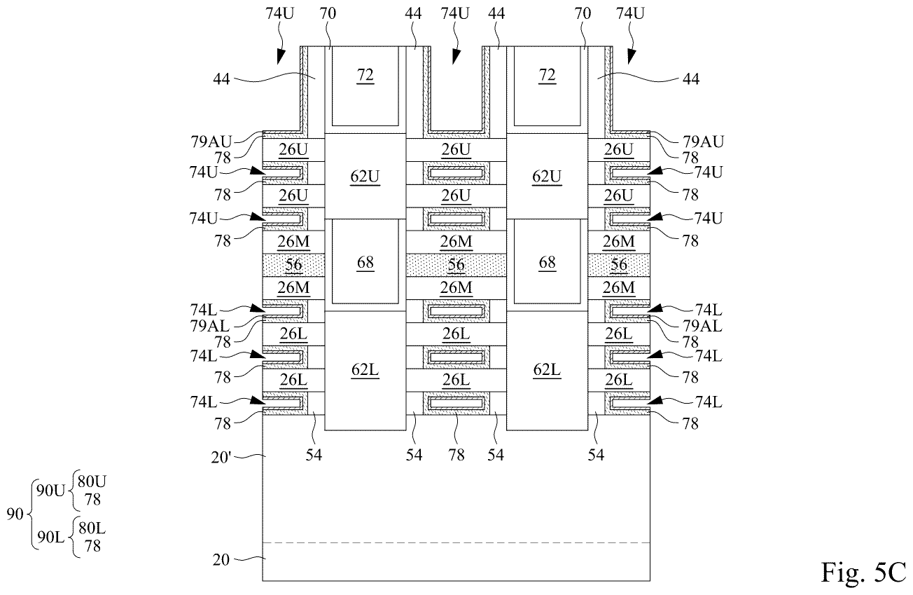

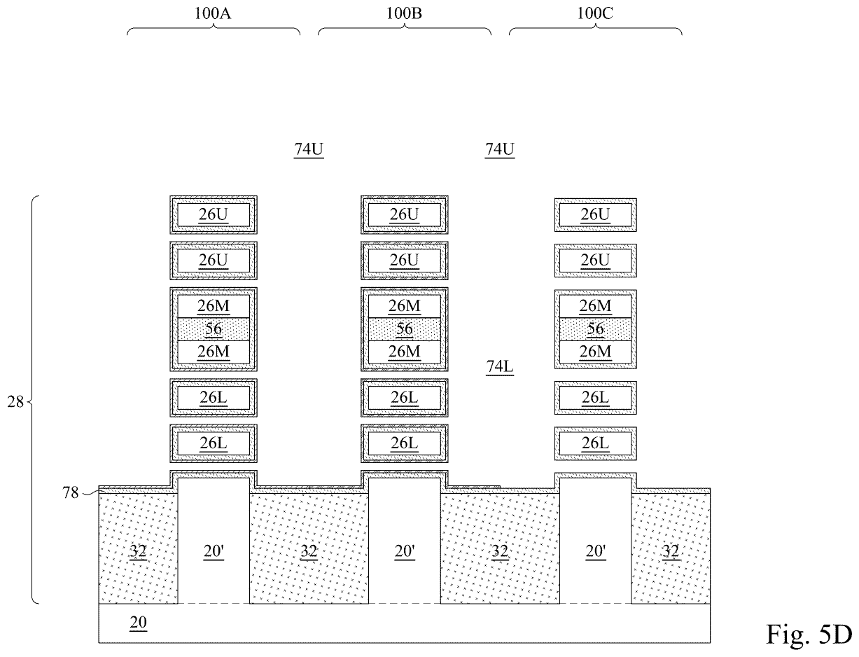

FIGS. 5A through 13D illustrate a replacement gate process to replace the dummy gate stacks 42 and the dummy nanostructures 24A with gate stacks 90. Each gate stack 90 includes gate dielectrics 78 and gate electrodes 80, and each gate electrode 80 includes a work function metal layer and a gap-filling metal (e.g., a fill metal structure) which are not separately illustrated. In addition, each gate stack 90 includes a lower gate stack 90L around the lower semiconductor nanostructures 26L and an upper gate stack 90U around the upper semiconductor nanostructures 26U, each of which may include their own respective components. The replacement gate process includes first removing the dummy gate stacks 42 and the remaining portions of the dummy nanostructures 24A. For example, the dummy gate stacks 42 are removed, and gate dielectrics 78 are deposited. The gate dielectrics 78 include lower gate dielectrics 78L around the lower semiconductor nanostructure 26L and upper gate dielectrics 78U around the upper semiconductor nanostructures 26U. As discussed in greater detail below, some steps of forming the gate dielectrics 78 may be performed simultaneously (e.g., deposition step(s)) and other steps of forming the gate dielectrics 78 may be performed separately (e.g., treatment step(s)) and do so by utilizing some embodiments discussed herein. Gate electrodes 80 are then formed over the gate dielectrics 78 and may include lower gate electrodes 80L formed over the lower gate dielectrics 78L and upper gate electrodes 80U formed over the upper gate dielectrics 78U.

In FIGS. 5A through 5D, the dummy gate stacks 42 are removed in one or more etching processes so that recesses 74 (e.g., trenches 74T) are defined between the gate spacers 44 and the upper portions of the semiconductor strips 28 are exposed. The remaining portions of the dummy nanostructures 24A are then removed through etching, so that the recesses 74 extend between the semiconductor nanostructures 26 (e.g., gaps 74G). As illustrated, the recesses 74 may include upper recesses 74U adjacent to and between the upper semiconductor nanostructures 26U and lower recesses 74L adjacent to and between the lower semiconductor nanostructures 26L. Note that an invisible boundary between the upper recesses 74U and the lower recesses 74L may be considered as being located laterally adjacent to the dielectric isolation layer 56 which separates the upper semiconductor nanostructures 26U from the lower semiconductor nanostructures 26L. In the etching process, the material of the dummy nanostructures 24A is etched at a faster rate than the materials of the semiconductor nanostructures 26, the dielectric isolation layers 56, and the inner spacers 54. The etching may be isotropic. For example, when the dummy nanostructures 24A are formed of silicon-germanium, and the semiconductor nanostructures 26 are formed of silicon, the etch process may include a wet etch process using tetramethylammonium hydroxide (TMAH), ammonium hydroxide (NH₄OH), or the like.

Then, gate dielectrics 78 are deposited in the recesses 74 between the gate spacers 44 and on the exposed semiconductor nanostructures 26. The gate dielectrics 78 are conformally formed on the exposed surfaces of the recesses 74 (the removed gate stacks 42 and the dummy nanostructures 24A) including the semiconductor nanostructures 26 and the gate spacers 44. In some embodiments, the gate dielectrics 78 wrap around all (e.g., four) sides of the semiconductor nanostructures 26. As illustrated, one or more layers of the gate dielectrics 78 may form a continuous ring or loop around multiple features, such as an uppermost nanostructure of the lower semiconductor nanostructures 26L, the dielectric isolation layer 56, and a lowermost nanostructure of the upper semiconductor nanostructures 26U. A portion of this gate dielectric 78 along the lower semiconductor nanostructure 26L may be considered part of the lower gate dielectrics 78L, and a portion of this gate dielectric 78 along the upper semiconductor nanostructure 26U may be considered part of the upper gate dielectrics 78U. In addition, the gate dielectrics 78 may be formed on the top surfaces of the fins 20′ and the STI regions 32; on the top surfaces, the sidewalls, and the bottom surfaces of the semiconductor nanostructures 26; and on the sidewalls of the gate spacers 44.

The gate dielectrics 78 may include an oxide such as silicon oxide or a metal oxide, a silicate such as a metal silicate, combinations thereof, multi-layers thereof, or the like. The gate dielectrics 78 may include a high-dielectric constant (high-k) material having a k-value greater than about 9.0, such as a metal oxide or a silicate of hafnium, aluminum, zirconium, lanthanum, manganese, barium, titanium, lead, and combinations thereof. The formation methods of the gate dielectrics 78 may include molecular-beam deposition (MBD), ALD, PECVD, and the like followed by a planarization process (e.g., a CMP) to remove portions of the gate dielectrics 78 above the second ILD 72. Although single-layered gate dielectrics 78 are illustrated, the gate dielectrics 78 may include multiple layers, such as an interfacial layer and an overlying high-k dielectric layer.

Referring to FIGS. 5C and 5D, as noted above, the gate dielectrics 78 may include multiple layers and may be formed differently in different device regions 100A, 100B, 100C. For example, the gate dielectrics 78 may be formed simultaneously in all illustrated device regions 100. Afterward, optionally, some device regions 100 may be masked while a variant gate dielectric 79 is formed over the gate dielectrics 78 in unmasked regions 100. In the illustrated example, device regions 100B and 100C may have been masked in order to form variant gate dielectric 79A in device region 100A. Similarly, device regions 100A and 100C may have been masked in order to form variant gate dielectric 79B in device region 100B. Alternatively, device region 100C may have been masked in order to form variant gate dielectric 79B in device regions 100A and 100B, and then device region 100B was also masked in order to convert variant gate dielectric 79B to variant gate dielectric 79A in device region 100A. However, any suitable combination of patterning, deposition, and treatment steps may be performed to form varying gate dielectrics 78 and/or 79 in the device regions 100. For simplicity of subsequent discussion, the gate dielectrics 78 and 79 may be referred to collectively as the gate dielectrics 78, unless specified otherwise.

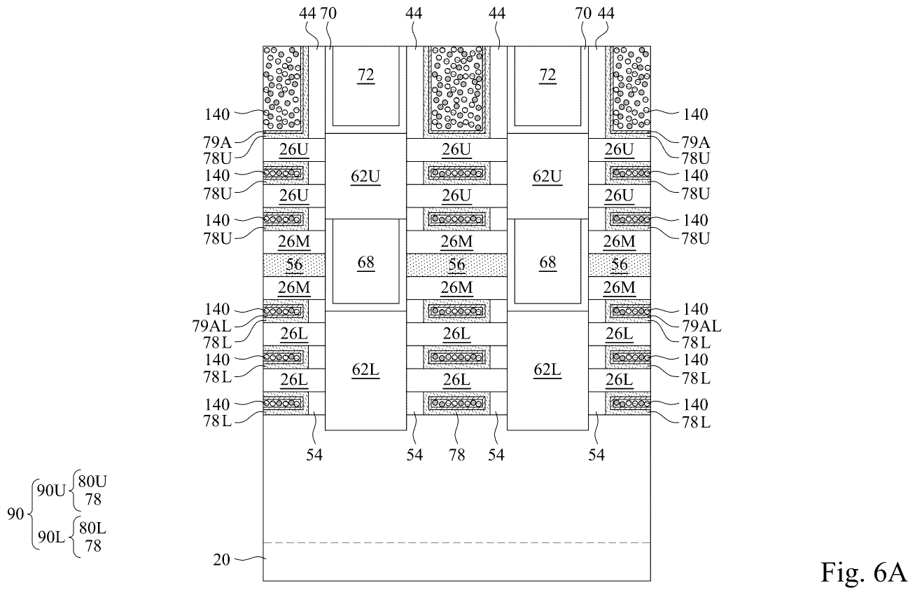

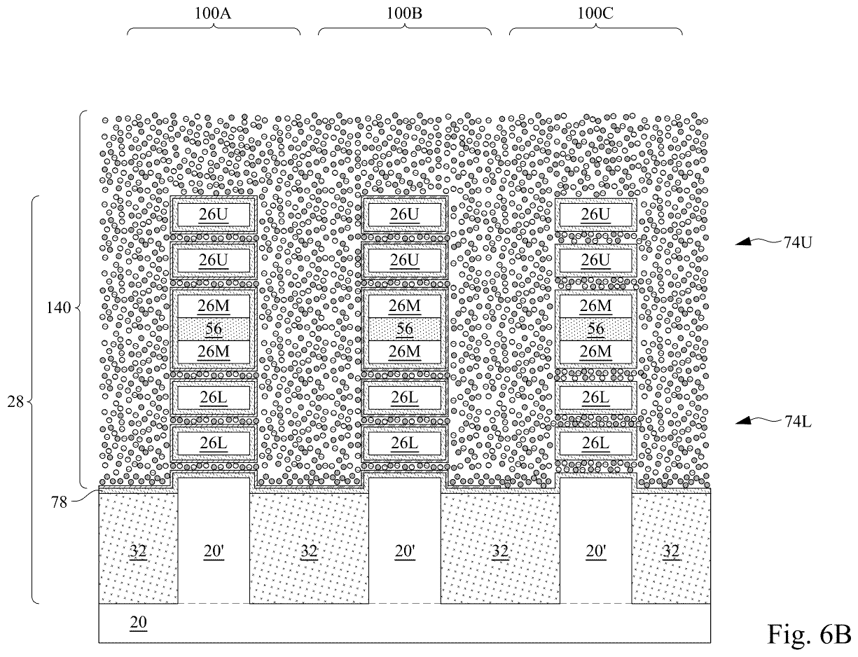

FIGS. 6A through 12B illustrate treatment processes to tune the upper gate dielectrics 78U and/or the lower gate dielectrics 78L in different ways from one another. For example, a directed self-assembly (DSA) material may be used to form a dummy fill material which may act as a mask (or assist in creating a mask) for the lower gate dielectrics 78 during such treatment processes. In some embodiments, a polymer solution (e.g., provided or prepared) referred to as an unassembled DSA material 140 may be coated over the structure and in the recesses 74. The polymers of the polymer solution may be block copolymers wherein each block copolymer molecule includes a first component chain and a second component chain. In accordance with various embodiments, the block copolymer molecules may start to assemble such that the first component chains align within the lower recesses 74L and the second component chains align within the upper recesses 74U. This early stage of alignment may be referred to as a mid-assembled DSA material 142 which includes two distinguishable layers: the lower and the upper mid-assembled DSA material layers 142L and 142U. A treatment process then converts the DSA material into an assembled DSA material 144 which includes two further distinguishable layers: a dummy fill material 150 (e.g., the second component chains) and an upper assembled DSA material layer 144U. After the treatment process, the upper assembled DSA material layer 144U (e.g., the first component chains) may be removed while the second component chains remain. A dipole film may then be formed over the now exposed upper gate dielectrics 78U, and a treatment process may be performed to drive or diffuse dopants from the dipole film into the upper gate dielectrics 78U. After removing the dipole film and the dummy fill material, formation of the gate stack 90 (e.g., the lower and upper gate electrodes 80L and 80U) may be completed.

In FIGS. 6A and 6B, a directed self-assembly (DSA) material 140 is applied over the structure and in the recesses 74, in accordance with some embodiments. The DSA material 140 may be provided or prepared in the form of a solution (e.g., a polymer solution or mixture such as a suspension) which substantially fills portions of the recesses 74 between adjacent semiconductor strips 28 (e.g., the fins 20′ and stacks of the semiconductor nanostructures 26). The solution may include polymer chains (e.g., block copolymer) with component chains having certain properties which allow for a desired assembly in some conditions. For example, due to the properties of the block copolymer, the DSA material 140 may be capable of separating or being separated into a plurality of layers.

As discussed above, in accordance with some embodiments, each of the polymer chains of the DSA material may be a block copolymer. The block copolymer may include a first component chain and a second component chain bonded to one another. One of the component chains (e.g., the first component chain) may be less hydrophilic (e.g., hydrophobic) and less reactive (e.g., low reactivity), The other of the component chains (e.g., the second component chain) may be a polymer chain which has been modified to include an attachment group which makes the second component chain more reactive (e.g., high reactivity). In some embodiments, the first component chain may have a low susceptibility to curing or bonding with the gate dielectrics 78, while the second component chain may have a high (or higher) susceptibility to curing and bonding with the gate dielectrics 78. Further, the first component chain may have a low ultraviolet (UV) absorption (e.g., being substantially transparent) while the second component chain may have a high (or higher) UV absorption. Further, the attachment group that is attached to the second component chain may be reactive with the gate dielectrics 78 (e.g., hydroxyl groups (—OH)) and with other attachment groups on other second component chains.

In various embodiments, the first component chain may include a first block polymer of polystyrene (PS). The second component chain may include a second block polymer of poly(methyl methacrylate) (PMMA), poly(2-vinylpyridine) (P2VP), polybutadiene (PB), poly(dimethylsiloxane) (PDMS), poly(acrylic acid) (PAA), poly(ethylene oxide) (PEO), or the like, which has been modified with an attachment group (e.g., azidated to include azide functional groups (—N₃)). The block copolymer comprises polystyrene (e.g., the first block polymer) being bonded to one of the listed second block polymers (as modified). As such, the block copolymer may comprise polystyrene-block-poly(methyl methacrylate) (PS-b-PMMA), polystyrene-block-poly(2-vinylpyridine) (PS-b-P2VP), polystyrene-block-polybutadiene (PS-b-PB), polystyrene-block-poly(dimethylsiloxane) (PS-b-PDMS), polystyrene-block-poly(acrylic acid) (PS-b-PAA), polystyrene-block-poly(ethylene oxide) (PS-b-PEO), or the like, wherein the respective latter block has been modified with an attachment group (e.g., azide groups).

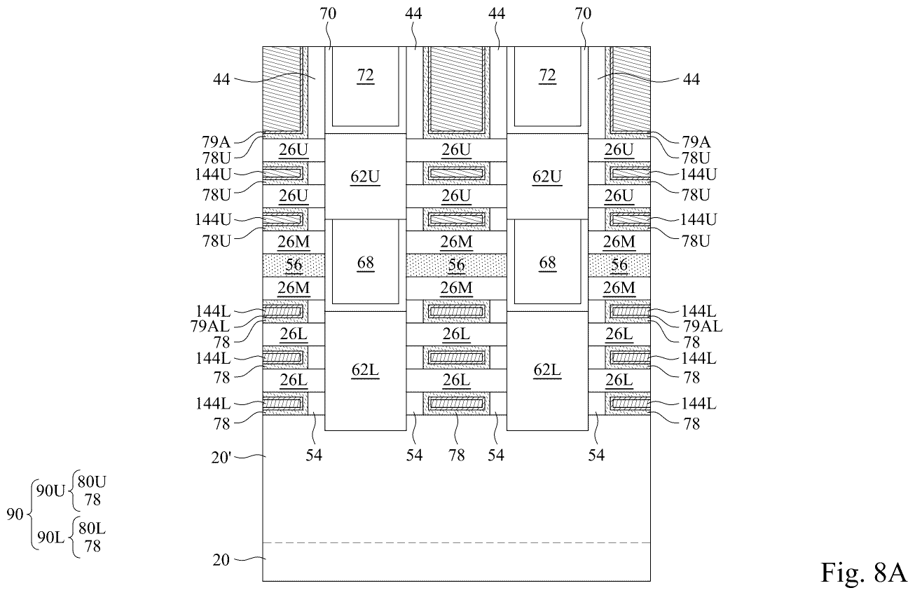

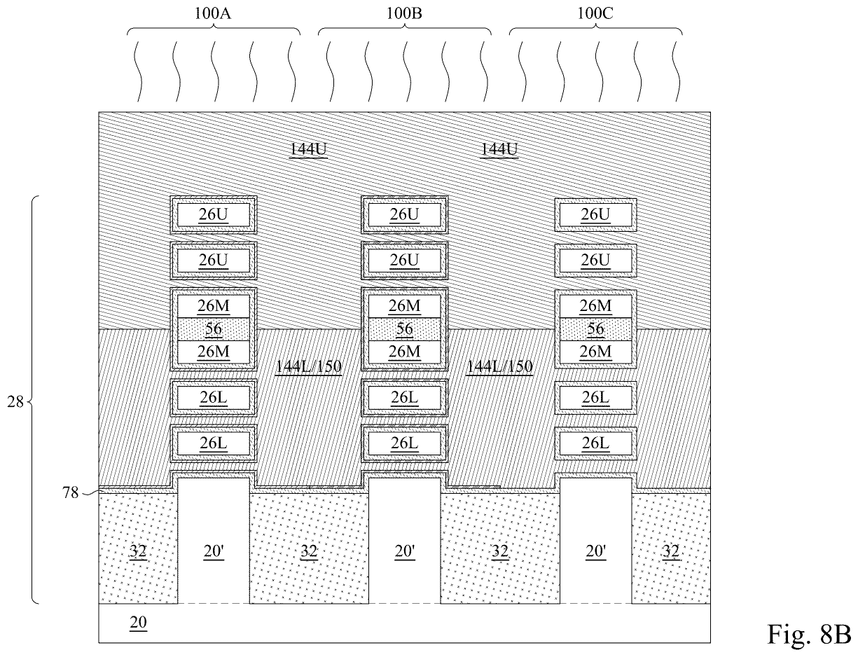

The unassembled DSA material 140 may be prepared and deposited in the form of a polymer solution or mixture comprising the above-described block copolymer dissolved or suspended in a solvent. The block copolymer may have a concentration of about 1 wt % to about 10 wt % in the solvent which may comprise toluene, tetrahydrofuran, chloroform, dichloromethane, the like, or a combination thereof. In addition, the mixture may further include a stabilizer to prevent photodegradation, such as benzophenones and/or hindered amine light stabilizers (HALS). Further, the mixture may be free of photoinitiator additives or cross-linking additives because the attachment group (e.g., the azide group) may provide such capabilities, as discussed in greater detail below (see FIGS. 8A and 8B). In some embodiments, the DSA material 140 may be applied by coating (e.g., spin-coating) the mixture over the structure and into the recesses 74. After application, the DSA material 140 may have a substantially planar top surface within process variation.

Advantages are achieved by the attachment group being an azide group. For example, after depositing the DSA material 140 over the structure, the azide group (e.g., the —N≡N group of the resonance structures) has a tendency to adsorb onto metal oxide surfaces (e.g., hydroxyl groups). Much of the surface area of the gate dielectrics 78 (e.g., the lower gate dielectrics 78L) extends along the underlying STI regions 32, and, accordingly, a large proportion of the hydrophilic chains (e.g., the second component chains) of the block copolymers will attach to this portion of the lower gate dielectrics 78L. The azide groups thus assist in starting to align the block copolymers immediately upon deposition of the DSA material 140. It should be appreciated that the adsorption of the azide groups to the gate dielectrics 78 may be through physical adsorption or weak interactions (e.g., van der Waals forces or hydrogen bonding). As such, the adsorption is physical, non-covalent, and reversible, so that the adsorbed azide group maintains its chemical structure (e.g., among its resonance structures), which will be helpful during subsequent processing steps (see, e.g., FIGS. 8A and 8B).

In accordance with some embodiments, the block copolymers are synthesized to have a uniform length. In particular, the block copolymers are synthesized and, optionally, filtered to have a polydispersity index of less than or equal to about 1.2 (such as less than or equal to about 1.1). Similarly, the second component chains of the block copolymers may have a polydispersity index of less than or equal to about 1.1. It should be appreciated that the polydispersity index of a sample of polymer chains indicates the degree of heterogeneity (or uniformity) of molecular weights (e.g., particle sizes or molecular masses) of the polymer chains in the sample. As such, a polydispersity index being close to 1 (e.g., less than about 1.2) may indicate a highly uniform sample. For example, the polydispersity index may be a ratio of a weight average molecular weight of the sample to the number average molecular weight of the sample. The number average molecular weight may be calculated by summing the molecular weight of each polymer chain and finding the average of the sum. In addition, the weight average molecular weight may be calculated by summing the molecular weight of each polymer chain multiplied by its molecular weight (e.g., squaring the molecular weight) and finding the average of the sum. The weight average molecular weight gives greater proportions to heavier (e.g., larger or longer) polymer chains, which may have disproportionately greater effects on the chemical properties of the sample than the lighter (e.g., smaller or shorter) polymer chains.

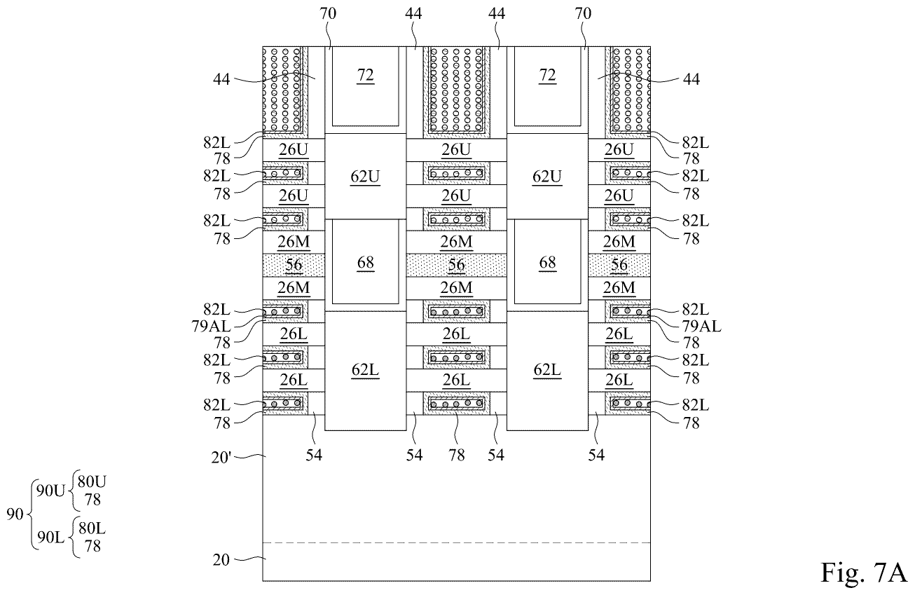

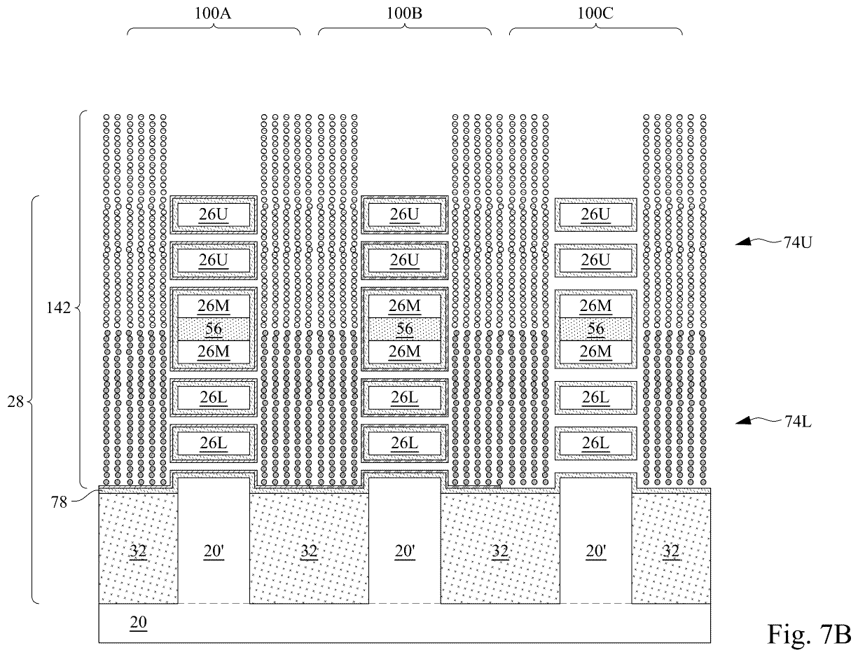

In FIGS. 7A and 7B, the DSA material 140 may start to (or continue to) assemble after being placed or maintained in an ambient comprising air, nitrogen, or a suitable ambient to allow the block copolymers to self-assemble into a mid-assembled DSA material 142. The attachment groups adsorb to hydroxyl groups along the lower gate dielectrics 78L along the bottom surfaces of the recesses 74. Being hydrophobic, the first component chains will tend to extend away from the gate dielectrics 78. As a result, a majority of the recesses 74 will include the second component chains aligning with one another while the respective first component chains align with one another as well. As illustrated, the mid-assembled DSA material 142 may exhibit two material layers, wherein the lower recesses 74L are substantially filled with the second component chains and the upper recesses are substantially filled with the first component chains. Note that for the sake of simplicity, FIG. 7A may provide a general sense of the block copolymer chains disposed between the narrower spaces.

As a result of the uniform length (e.g., the polydispersity index being close to 1) of the block copolymers, a plane of separation between the first component chains and the second component chains may be substantially flat. Note that, although not specifically illustrated, some of the block copolymers may attach to portions of the gate dielectrics 78 disposed around the nanostructures 26. However, such attachments within the gaps 74G of the recesses 74 between adjacent nanostructures 26 may be low due to steric hindrance from the few of the block copolymers that are able to reach such gaps 74G. In addition, attachments of the block copolymer along outer surfaces of the gate dielectrics 78 disposed around the nanostructures 26 may also be few in comparison to the attachments of the block copolymer along the bottom surfaces of the trenches 74T of the recesses 74 (e.g., directly above the STI regions 32). As such, a majority of the block copolymer may assemble as illustrated.

In accordance with some embodiments, when preparing or acquiring the DSA material 140, lengths of the block copolymers and the component chains are selected to yield the results as illustrated and described above. For example, a length of the second component chain may be selected in order for the plane of separation between the first component chains and the second component chains to be at a level between the top surface and the bottom surface of the dielectric isolation layers 56. In addition, a length of the first component chain may be selected in order for the first component chains (e.g., those attached to second component chains which are attached to the bottom surfaces of the recesses 74) to extend above the upper semiconductor nanostructures 26U. As such, these first component chains would provide steric hindrance to reduce the number of the attachment groups that are able to attach to the gate dielectrics 78 around the upper semiconductor nanostructures 26U.

For example, the length of the second component chain as it would extend in the solution of the DSA material 140/142 may be selected based on a height of the dielectric isolation layers 56 above the bottom of the trenches 74T (e.g., above the STI regions 32). In particular, the length of the second component chains may be selected to be within the heights of the lowermost surface and uppermost surface of the dielectric isolation layers 56. As a result, the plane of separation of the mid-assembled DSA material 142 (as well as the subsequently assembled DSA material 144) will be level with the dielectric isolation layers 56. In addition, the length of the first component chain as it would extend in the solution of the DSA material 140/142 may be selected based on a height of a topmost surface of the upper semiconductor nanostructures 26U above the dielectric isolation layers 56. In particular, the length of the first component chains should be greater than this particular height of the upper semiconductor nanostructures 26U. As a result, the first component chains of the mid-assembled DSA material 142 (as well as the subsequently assembled DSA material 144) will be above the upper semiconductor nanostructures 26U.

In FIGS. 8A and 8B, a curing process may be performed to cure the mid-assembled DSA material 142 in order to form an assembled DSA material 144. As noted above, the assembled DSA material 144 comprises a dummy fill material 150 (e.g., the second component chains) and an upper assembled DSA material 144U (e.g., the first component chains). In accordance with some embodiments, the curing process utilizes ultraviolet (UV) curing, wherein UV light is absorbed by the first component chains after passing through the first component chains. The UV light further attaches the second component chains to the gate dielectrics 78 and triggers cross-linking among the second component chains. After these changes, the second component chains become further distinguishable from the first component chains, and the cured and cross-linked second component chains may be referred to as the dummy fill material 150.

In some embodiments, the curing process may further include an anneal to evaporate the solvent and further distinguish the first component chains from the cured second component chains (e.g., increase phase separation). The anneal may be performed at a temperature ranging from about 150° C. to about 450° C. The curing process (and optional anneal) may be performed for a duration ranging from about 1 minute to about 180 minutes. Note that the anneal may be performed separately after the curing process or omitted entirely.

In embodiments in which the attachment groups comprise azide groups, the azide groups undergo photolysis when exposed to UV light. The photolysis reaction occurs because azide absorbs UV light within the range of about 150 nm to about 250 nm, which excites an electron pair on one of the nitrogen atoms into the pi (Π*) electron transition state. The photolysis reaction includes the azide groups decomposing into nitrene groups and nitrogen gas (N₂)—the latter of which being released. The nitrene groups have a high reactivity, which serves multiple benefits. For example, the azide groups adsorbed on the lower gate dielectric 78L may become the nitrene groups which then form covalent bonds with the hydroxyl groups of the lower gate dielectric 78L. In addition, the nitrene groups will react with and bond to other nearby molecules of the block copolymers (e.g., the hydrophilic chains of the block copolymers). The cross-linking effectively locks the second component chains together to convert the second component chains of the DSA material into a network structure (e.g., the dummy fill material DFL). Indeed, vinyl groups do not have such a tendency to cross-link without the presence of photoinitiator additives.

In accordance with various embodiments, the curing process increases the etch selectivity between the first component chains and the second component chains. In other words, an etch selectivity (e.g. a post-curing etch selectivity) between the first component chains (e.g., the upper assembled DSA material 144U) and the cured second component chains (e.g., the dummy fill material 150) is greater than an etch selectivity (e.g., a pre-curing etch selectivity) between the first component chains (e.g., the upper mid-assembled or assembled DSA material 142U, 144U) and the uncured second component chains (e.g., the lower mid-assembled DSA material 142L). It should be appreciated that some of the second component chains which are attached to the upper gate dielectrics 78U within the gaps 74G of the recesses 74 may exhibit relatively low cross-linking.

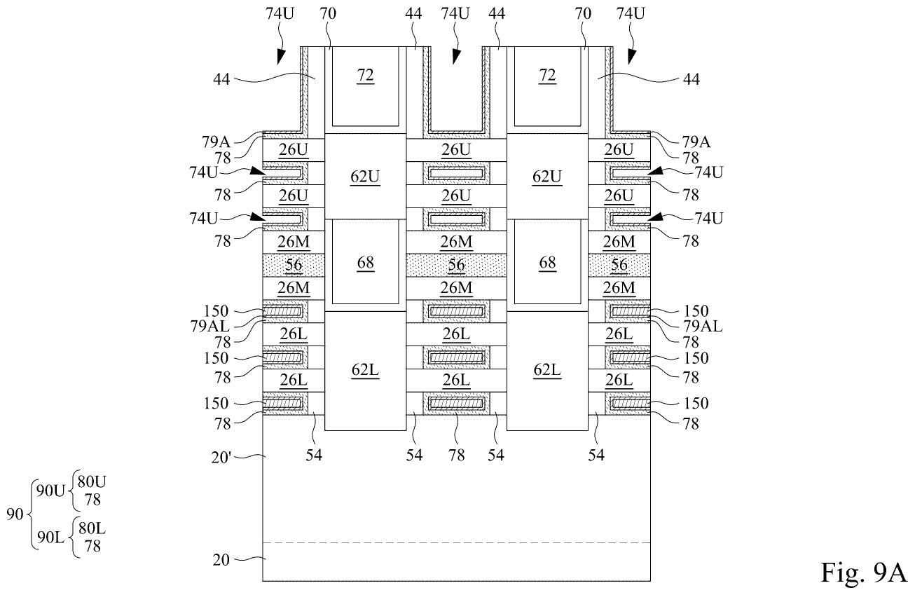

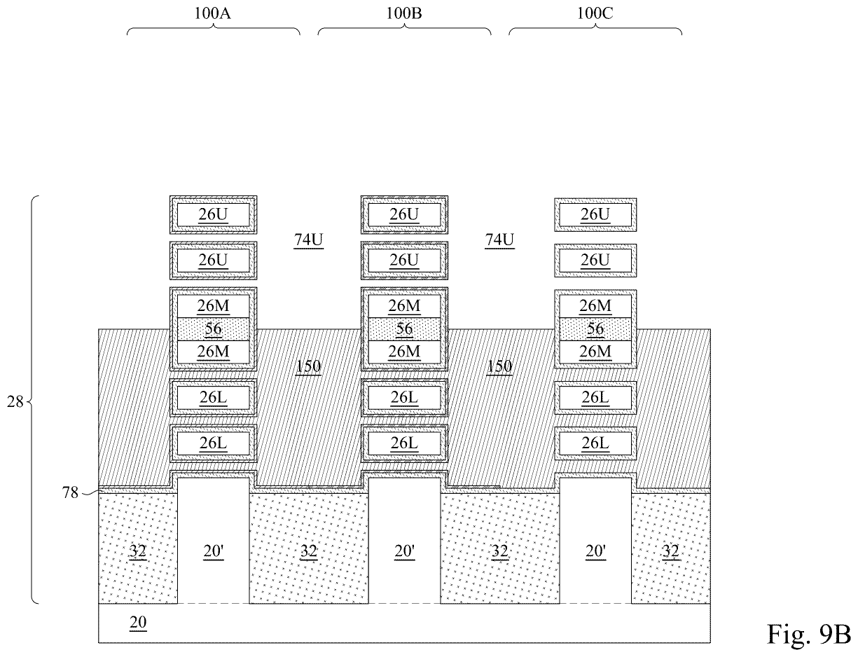

Optionally, after the curing process, a CMP process may be performed to thin the upper assembled DSA material 144U, so that the top surfaces of the upper assembled DSA material 144U are slightly higher than the upper semiconductor nanostructures 26U. This may reduce the duration and improve control of a subsequent etch process (see FIGS. 9A and 9B).

In FIGS. 9A and 9B, an etch process may be performed to remove the upper assembled DSA material 144U. The etch process may be isotropic. For example, the etch process may be a wet etch which removes the upper assembled DSA material 144U while the dummy fill material 150 remains substantially unetched. In accordance with some embodiments, the upper assembled DSA material 144U may be etched using etchants such as toluene, tetrahydrofuran, chloroform, dichloromethane, or the like. The etchant may include a same chemical as the solvent of the unassembled DSA material 140 as deposited.

As illustrated, the etch process to remove the upper assembled DSA material 144U exposes the underlying dummy fill material 150. The plane of separation between the first component chains and the second component chains substantially becomes an upper surface of the dummy fill material 150. As such, the upper surface of the dummy fill material 150 is lower than top surfaces of, and higher than bottom surfaces of, the dielectric isolation layers 56. The upper surface of the dummy fill material 150 may also be slightly higher or lower to be level with the upper or lower nanostructures 26 that are immediately adjacent to the dielectric isolation layers 56.

As noted previously, some of the attachment groups and corresponding second component chains may have attached to be within the gaps 74G of the recesses 74 between the upper semiconductor nanostructures 26U where they may have been substantially shielded from the UV light of the curing process. As such, these second component chains may be substantially removed during the etch process due to having a lower etch selectivity with the upper assembled DSA material 144U (e.g., the first component chains) as compared to the higher etch selectivity between the dummy fill material 150 (e.g., the cross-linked second component chains) with the upper DSA material 142U, 144U.

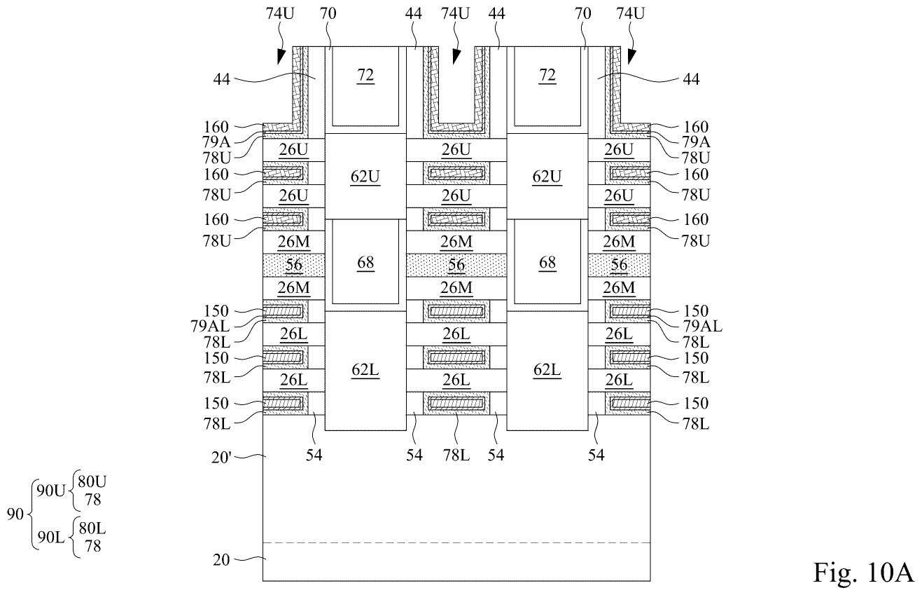

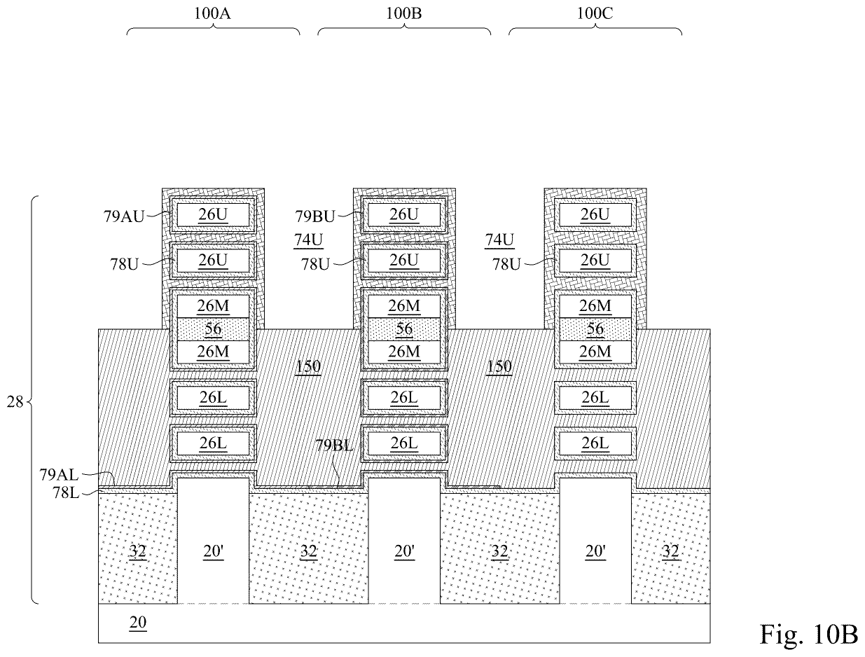

In FIGS. 10A and 10B, upper dipole films 160 are formed around the exposed upper gate dielectrics 78U. The upper dipole films 160 are deposited on the upper gate dielectrics 78U in device regions 100A, 100B, and 100C. However, it should be appreciated that any of the device regions 100 may be masked if there is no intention of treating the upper gate dielectrics 78U in such regions. The upper dipole films 160 may be formed through a suitable deposition process (e.g., CVD, ALD, or the like), which may or may not be followed by an etch process.

The upper dipole films 160 may comprise a dipole dopant selected for the upper gate dielectrics 78U of the upper nanostructure-FET. The dipole dopants, when incorporated into the upper gate dielectrics 78U, may increase the effective work functions and hence reduce the threshold voltages of the corresponding upper nanostructure-FETs. In accordance with embodiments in which the upper nanostructure-FET is an n-type FET, the upper dipole films 160 may be a metal oxide or a metal nitride or, e.g., comprise a material selected from one or more of an oxide(s), a nitride(s), and/or a carbide(s) of an n-type dipole dopant(s) such as La, Sr, Y, Er, Sc, Mg, the like, or combinations thereof. In embodiments in which the upper nanostructure-FET is a p-type FET, the upper dipole films 160 may be a metal oxide or a metal nitride or, e.g., comprise a material selected from one or more of an oxide(s), a nitride(s), and/or a carbide(s) of a p-type dipole dopant(s) such as Al, Ga, Zn, Ti, Ta, the like, or combinations thereof.

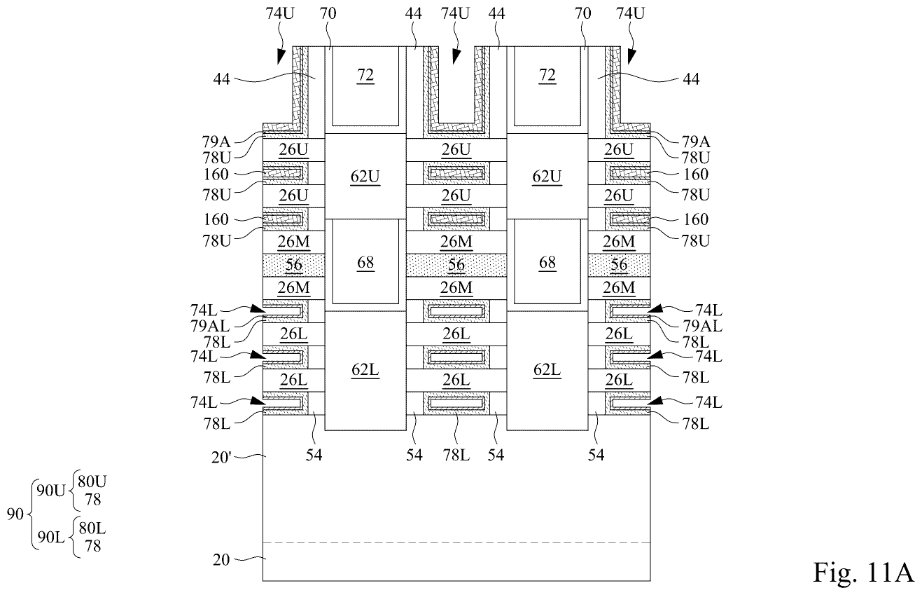

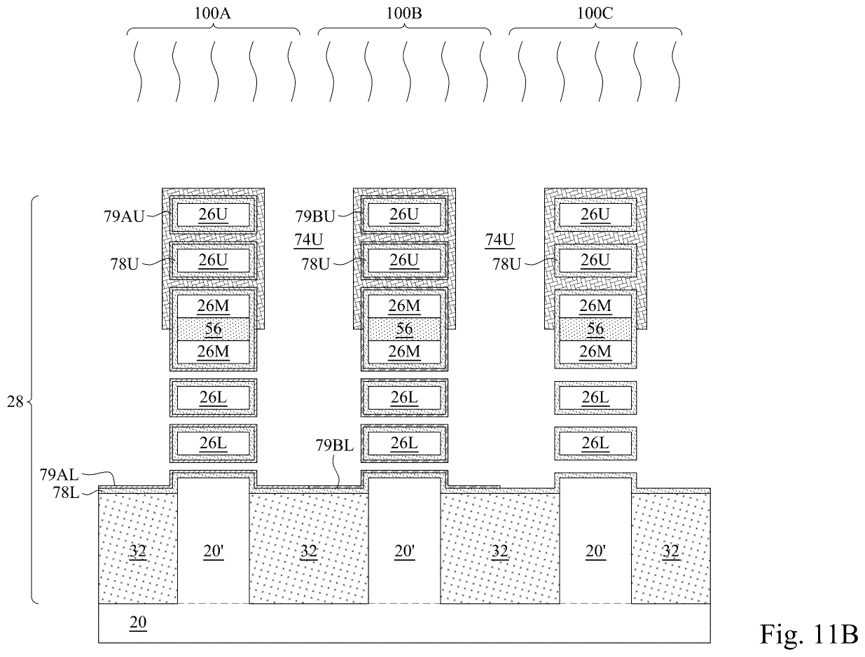

In FIGS. 11A and 11B, the dummy fill material 150 is removed and a treatment process is performed to drive the dipole dopants from the upper dipole films 160 into the respective underlying upper gate dielectrics 78U (e.g., including variant gate dielectrics 79, 79U). The dummy fill material 150 may be removed using a thermal ashing process. For example, the thermal ashing process may be performed at temperatures ranging from 300° C. to 700° C.

In accordance with some embodiments, the treatment process to drive in the dipole dopants may comprise an anneal using a process gas selected from N₂, He, NH₃, Ar, the like, and mixtures thereof. The anneal helps to drive the dipole dopants in the upper dipole films 160 into the underlying high-k dielectric layer of the respective upper gate dielectrics 78U, and possibly into the underlying interfacial layer of the respective upper gate dielectrics 78U. This has the effect of adjusting (such as reducing) the threshold voltages of the resulting upper FETs. In accordance with some embodiments, the anneal may be performed through a soak annealing process, a spike rapid thermal annealing process, or the like. For example, when the soak annealing process is used, the anneal duration may range from about 5 seconds to about 5 minutes, and the temperature may be in the range of between about 500° C. and about 850° C.

Note that the thermal ashing process to remove the dummy fill material 150 may help to drive some of the dipole dopants into the upper gate dielectrics 78U. As such, the thermal ashing process may be performed in conjunction with or separately from the anneal of the dipole dopant treatment process. In other embodiments (not specifically illustrated), the dipole dopant treatment process may be performed before removing the dummy fill material 150.

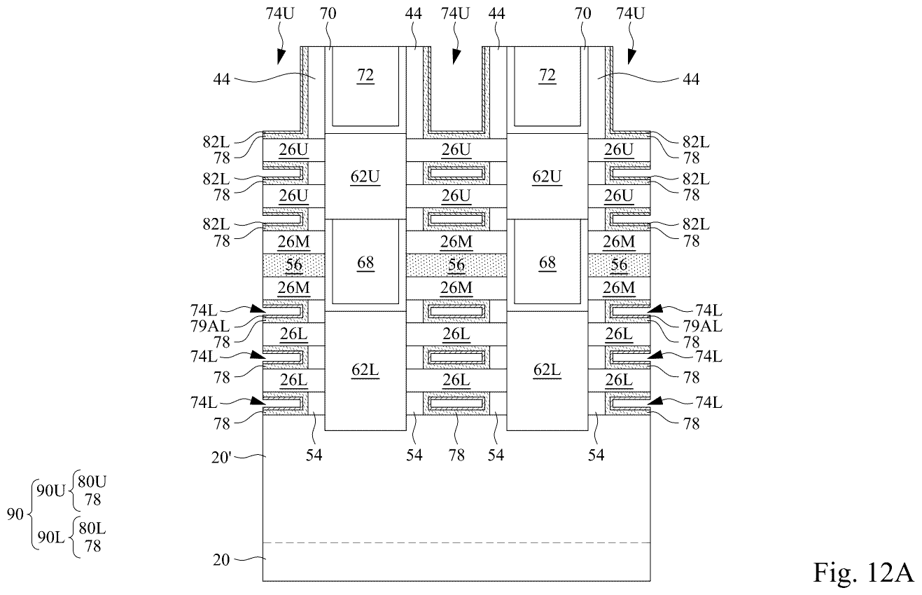

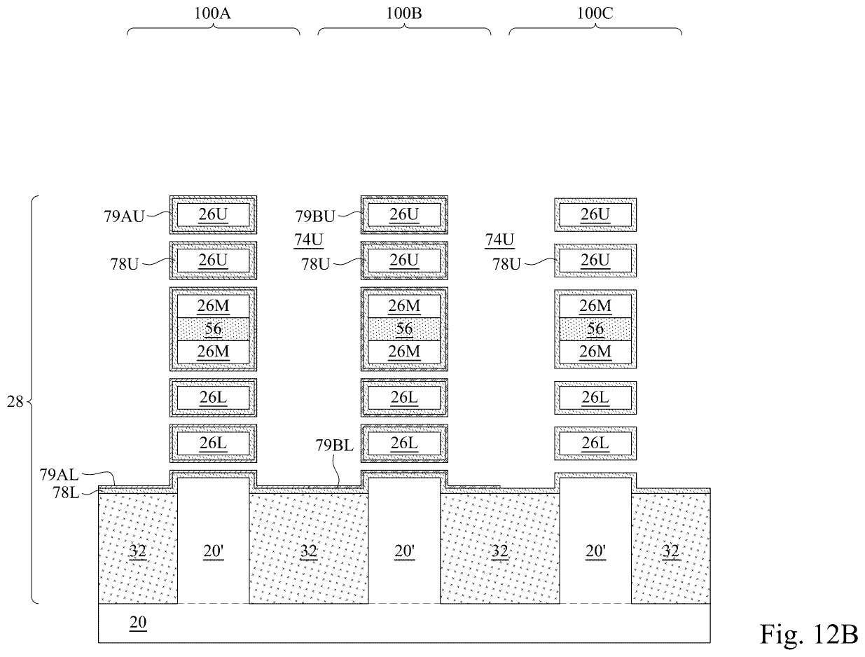

In FIGS. 12A and 12B, an etch process may then be performed to remove the upper dipole film 160 from the upper gate dielectrics 78U. The etch process may be an isotropic etching process, such as a wet etch. The etch process may use any suitable etchants based on the selected material of the upper dipole films 160.

In some embodiments (not specifically illustrated), formation of a dummy fill material may also be used to drive lower dipole dopants into the lower gate dielectrics 78L from lower dipole films formed around the lower gate dielectrics 78L. For example, the upper dipole films 160 may be formed and the dummy film material 150 may be removed to expose the lower gate dielectrics 78L, similarly as described above. Next, lower dipole films may be formed over and around the lower gate dielectrics 78L around the lower semiconductor nanostructures 26L and along the bottom of the recesses 74. The lower dipole films may be formed analogously as described above in connection with forming the upper dipole films 160. As such, the dipole dopant treatment process may be performed simultaneously for the upper gate dielectrics 78U and the lower gate dielectrics 78L. In embodiments in which the material of the lower dipole films also forms over the upper dipole films 160, the thickness of the upper dipole films 160 may prevent the lower dipole dopants from reaching the upper gate dielectrics 78U. In such embodiments, the upper dipole films 160 may be formed with a greater thickness than the lower dipole films to ensure the upper dipole films 160 provide sufficient protection. Afterward, the dipole films may be removed in parallel or series using any suitable methods.

In other embodiments (also not specifically illustrated), formation of the dummy fill material 150 may be used to drive lower dipole dopants into the lower gate dielectrics 78L—and not to drive upper dipole dopants into the upper gate dielectrics 78U (e.g., at least not at this same point in the fabrication of the stacking nanostructure-FETs). For example, an upper dummy material may be formed around the upper gate dielectrics 78U instead of forming the upper dipole film 160. The lower dipole film may be formed and a remainder of the process may be performed analogously as described above.

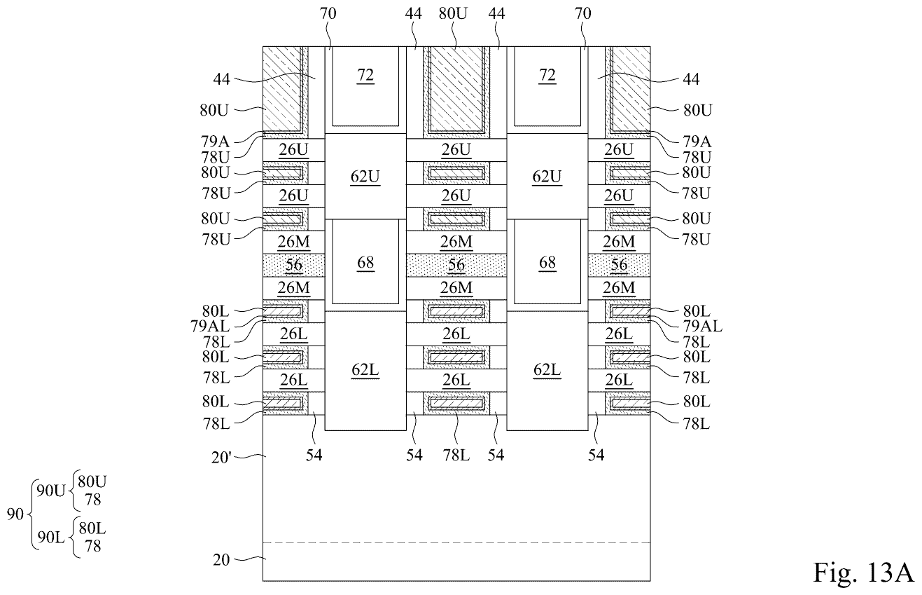

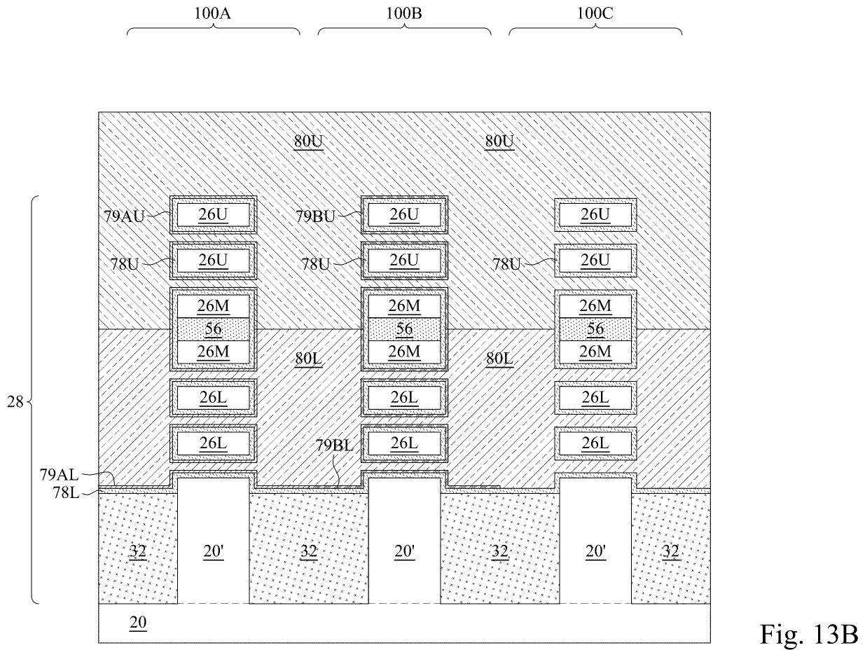

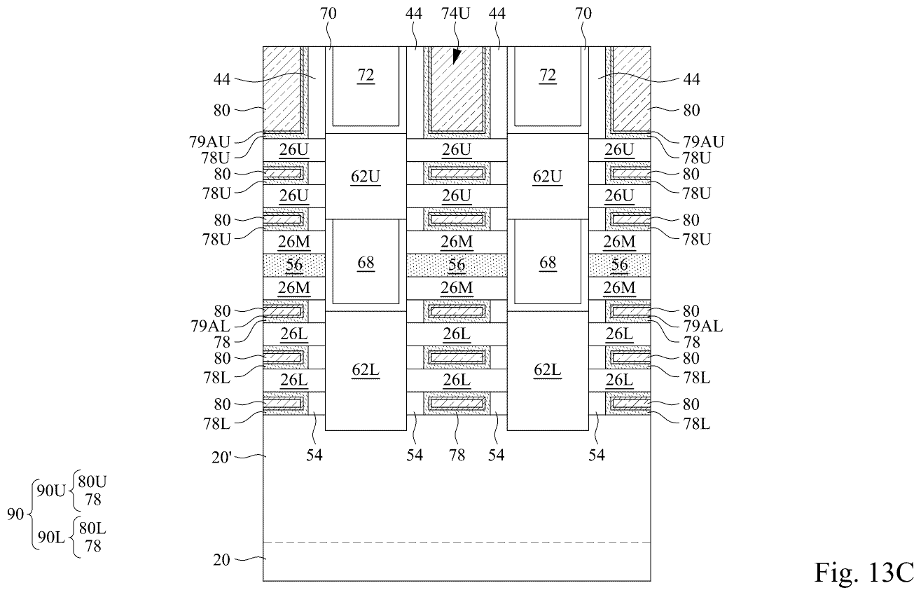

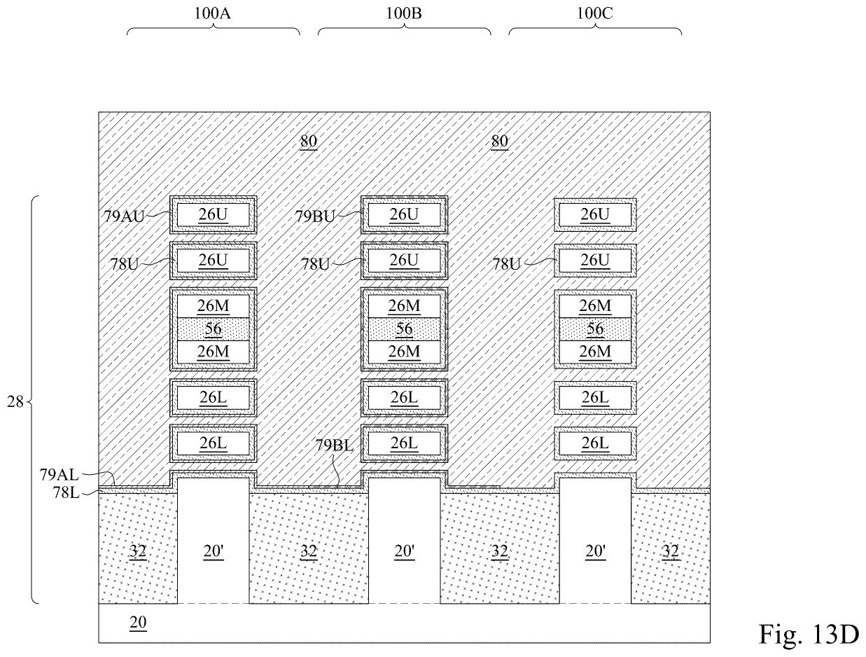

FIGS. 13A through 13D illustrate various embodiments of forming a gate electrode 80 comprising a lower and an upper gate electrode 80L and 80U. The lower gate electrodes 80L are formed on the lower gate dielectrics 78L around the lower semiconductor nanostructures 26L, and the upper gate electrodes 80U on the upper gate dielectrics 78U around the upper semiconductor nanostructures 26U. For example, the lower gate electrodes 80L wrap around the lower semiconductor nanostructures 26L, and the upper gate electrodes 80U wrap around the upper semiconductor nanostructures 26U. The gate electrodes 80 may be formed of various metal-containing materials such as tungsten, titanium, titanium nitride, tantalum, tantalum nitride, tantalum carbide, aluminum, ruthenium, cobalt, combinations thereof, multi-layers thereof, or the like. Although each of the gate electrodes 80 (e.g., each of the upper and lower gate electrodes 80U and 80L) is illustrated as a single layer, each of the gate electrodes 80 may include any number of work function tuning layers (e.g., work function metal (WFM) layers), any number of barrier layers, any number of glue layers, and a fill material.

Referring to FIGS. 13A and 13B, each of the gate electrodes 80 is formed of materials that are suitable for the device type of the particular nanostructure-FETs. For example, the work function metal layers of the respective gate electrodes 80 may include one or more material(s) that are suitable for the device type of the particular nanostructure-FETs. In some embodiments, the lower gate electrode 80L is p-type and includes one or more work function tuning layers suitable for a p-type FET, while the upper gate electrode 80U is n-type and includes one or more work function tuning layers suitable for an n-type FET, or vice versa. As such, each gate electrode 80 may include one of (or a suitable combination of) the various p-type and n-type work function layers. The p-type work function tuning layers may include titanium nitride, titanium aluminum, tantalum nitride, tungsten nitride, combinations thereof, or the like. The n-type work function tuning layers may include titanium aluminum, titanium aluminum carbide, tantalum aluminum, tantalum carbide, combinations thereof, or the like.

In some embodiments, the lower gate electrodes 80L may be formed by conformally depositing the gate electrode layer(s) (e.g., the lower work function metal layer(s) and the lower gap-filling metal) and then recessing the gate electrode layers. Any acceptable etch process, such as a dry etch, a wet etch, the like, or a combination thereof, may be performed to recess the gate electrode layer(s). The etching may be isotropic. Etching the lower gate electrodes 80L may expose the upper semiconductor nanostructures 26U.

For example, the lower work function metal layer is deposited in the recesses 74 over the gate dielectrics 78 around both the upper and lower semiconductor nanostructures 26U and 26L. The lower work function metal layer may be conformally formed over the gate dielectrics 78 as well as any barrier layers and/or glue layers (not separately illustrated). The lower work function metal layer may be formed of the same candidate materials and candidate processes as described above. In some embodiments, the lower work function metal layer comprises titanium nitride and is deposited using ALD, CVD, the like, or any suitable conformal deposition process.

After forming the lower work function metal layer, a lower gap-filling metal may be deposited in the recesses 74 over the lower work function metal layer, around the upper and lower semiconductor nanostructures 26U and 26L. The lower gap-filling metal may fill remainders of the recesses 74 around the upper and lower semiconductor nanostructures 26U and 26L and may be formed of the same candidate materials and candidate processes as described above. In some embodiments, the lower gap-filling metal comprises ruthenium, molybdenum, or an alloy thereof. For example, the lower gap-filling metal may be deposited using ALD, CVD, or combinations thereof.

One or more etch processes may be performed on the lower gap-filling metal and the lower work function metal layer to etch-back the lower gate electrode 80L and to expose the upper gate dielectrics 78U of the upper nanostructure-FETs. In some embodiments, the etch processes may include a dry etch process and may be selective to the material of the lower gap-filling metal, so that the lower gap-filling metal is etched at a faster rate than the lower work function metal layer. As such, the lower work function metal layer (e.g., located in the upper recess 74U) is exposed and serves as a hard mask to protect underlying features (e.g., the gate dielectrics 78 around the upper semiconductor nanostructures 26U). In some embodiments, the etch process may include any suitable etchants such as a chlorine-based etchant (e.g., chlorine (Cl₂)) or a sulfur-based etchant (e.g., sulfur hexafluoride (SF₆), or the like.

For example, the lower gap-filling metal may be etched until an upper surface is laterally adjacent to the dielectric isolation layers 56. In particular, the lower gap-filling metal is removed from the upper recess 74U while the lower recess 74L remains filled. After etching the lower gap-filling metal, an additional etch process (e.g., a wet etch process) may be performed to remove the lower work function metal layer (and any other layers of the lower gate electrodes 80L) from the gate dielectrics 78 around the upper semiconductor nanostructures 26U. In some embodiments, the etch process may include any suitable etchants such as a chemical solution of hydrogen peroxide (H₂O₂) and ammonium hydroxide (NH₄OH).

In some embodiments (not specifically illustrated), isolation layers may be optionally formed on the lower gate electrodes 80L. The isolation layers act as isolation features between the lower gate electrodes 80L and subsequently formed upper gate electrodes 80U. The isolation layers may be formed by conformally depositing a dielectric material (e.g., silicon oxide, silicon nitride, silicon oxynitride, silicon oxycarbonitride, combinations thereof, or the like) and subsequently recessing the dielectric material to expose the upper semiconductor nanostructures 26U.

After etching back the lower gap-filling metal and the lower work function metal layer (and any other corresponding layers) to form the lower gate electrodes 80L, the upper gate electrodes 80U are formed in the upper recesses 74U over the lower gate electrodes 80L. In particular, the upper gate electrodes 80U are formed over the upper gate dielectrics 78U around the upper semiconductor nanostructures 26U. As discussed above, the upper gate electrodes 80U may include the one or more suitable work function metal layers and an upper gap-filling metal. The layers of the upper gate electrodes 80U may be formed analogously as described above in connection with the lower gate electrodes 80L.

Referring to FIGS. 13C and 13D, the gate electrodes 80 may be formed with same materials for the upper and lower gate electrodes 80U and 80L. In particular, the dipole dopant processes described above may distinguish the upper and lower gate electrodes 80U and 80L between being n-type FETs and p-type FETs. As such, the steps of forming the one or more work function metal layers and the gap-filling metal can be performed for the entire gate electrode 80, similarly as described above.

Referring again to FIGS. 13A through 13D, a removal process may be performed to level top surfaces of the gate electrodes 80 with the second ILD 72. The removal process may be similar to the removal process described above after formation of the first ILD 68. In some embodiments, a planarization process such as a chemical mechanical polish (CMP), an etch-back process, combinations thereof, or the like may be utilized. After the planarization process, the top surfaces of the upper gate electrodes 80U, the gate dielectrics 78, the second ILD 72, and the gate spacers 44 are substantially coplanar (within process variations). Each respective pair of a gate dielectric 78 and a gate electrode 80 (including an upper gate electrode 80U and/or a lower gate electrode 80L) may be collectively referred to as a “gate structure” or a “gate stack” 90 (e.g., which include upper gate structures 90U and lower gate structures 90L). Each gate stack 90 extends along three sides (e.g., a top surface, a sidewall, and a bottom surface) of a channel region of a semiconductor nanostructure 26 (see FIG. 1). The lower gate structures 90L of the gate stacks 90 may also extend along sidewalls and/or a top surface of a semiconductor fin 20′.

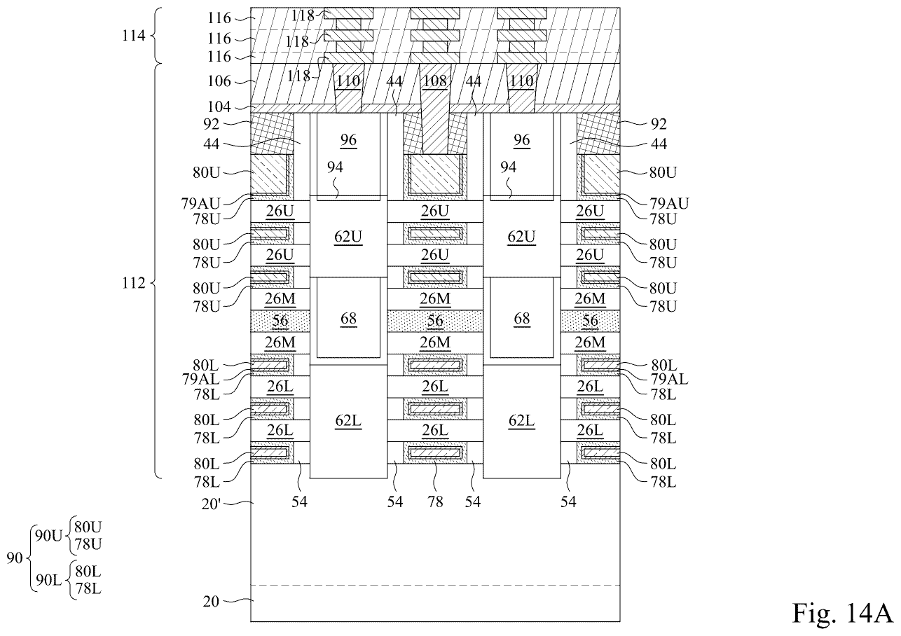

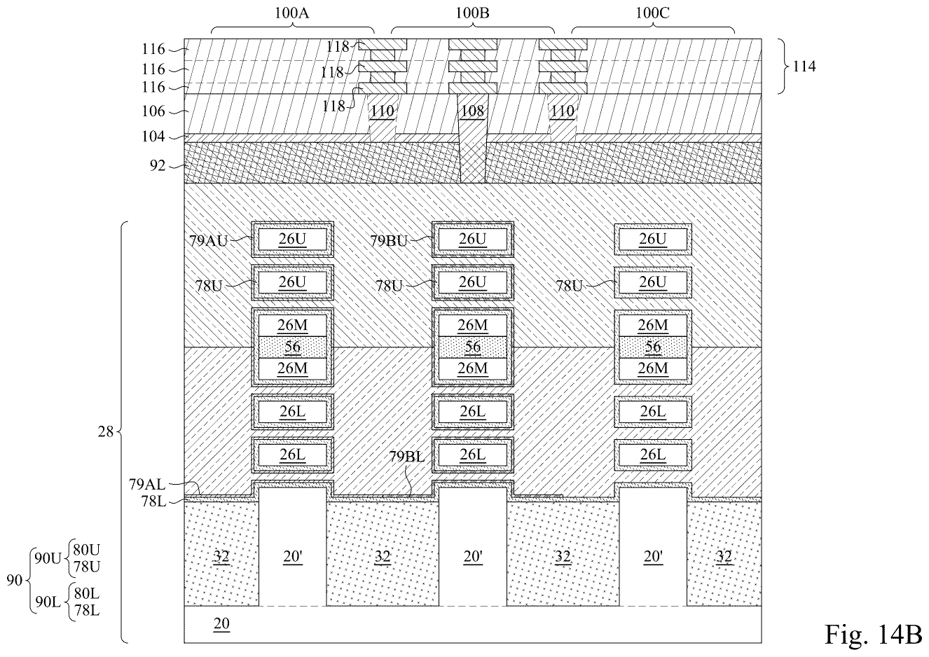

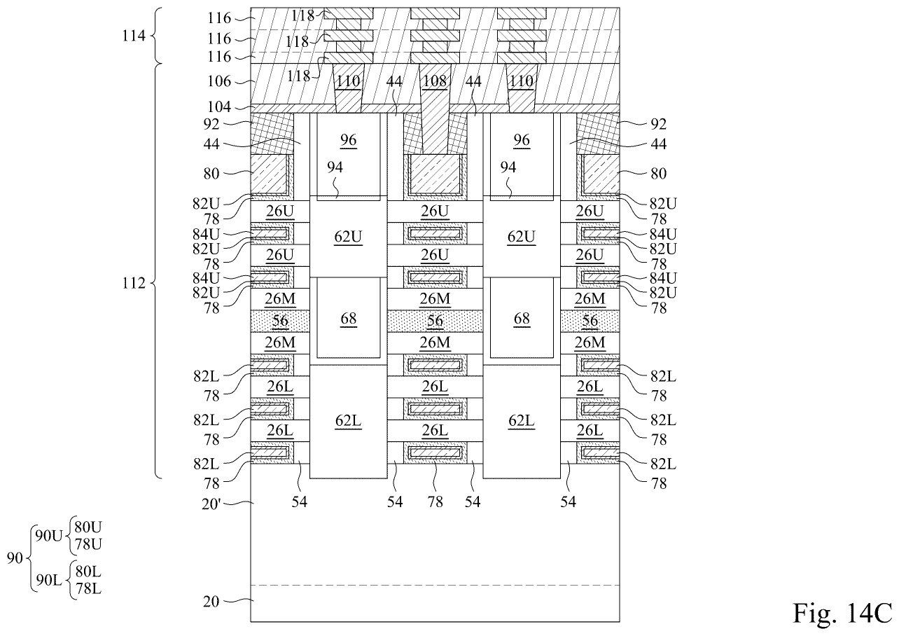

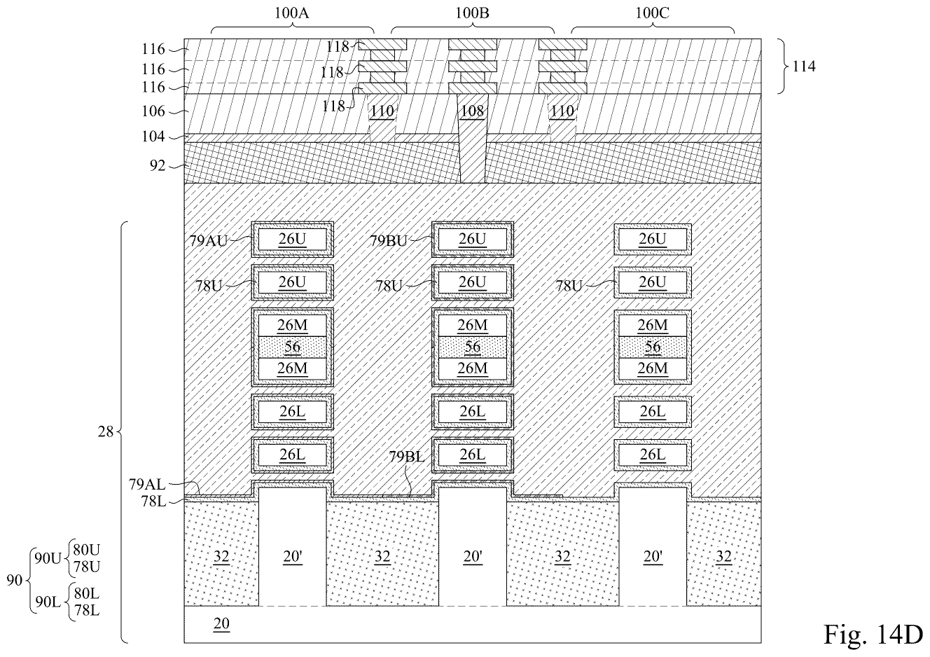

In FIGS. 14A and 14B, gate masks 92 are formed over the gate stacks 90, and metal-semiconductor alloy regions 94 and source/drain contacts 96 are formed through the second ILD 72 to electrically couple to the upper epitaxial source/drain regions 62U and/or the lower epitaxial source/drain regions 62L. For example, the gate stacks 90 may be recessed, and the resulting recesses are filled with a dielectric material such as silicon nitride, silicon carbonitride, silicon oxynitride, silicon oxycarbonitride, the like, or a combination thereof. A planarization process may then be performed to remove the excess portions of the dielectric material over the second ILD 72.

As an example to form the source/drain contacts 96, openings are formed through the second ILD 72 and the second CESL 70 using acceptable photolithography and etching techniques. A liner (not separately illustrated), such as a diffusion barrier layer, an adhesion layer, or the like, and a conductive material are formed in the openings. The liner may include titanium, titanium nitride, tantalum, tantalum nitride, or the like. The conductive material may be cobalt, tungsten, copper, a copper alloy, silver, gold, aluminum, nickel, or the like. A removal process may be performed to remove excess material from the top surfaces of the gate spacers 44 and the second ILD 72. The remaining liner and conductive material form the source/drain contacts 96 in the openings. In some embodiments, a planarization process such as a CMP, an etch-back process, combinations thereof, or the like is utilized. After the planarization process, the top surfaces of the gate spacers 44, the second ILD 72, and the source/drain contacts 96 are substantially coplanar (within process variations).

Optionally, metal-semiconductor alloy regions 94 are formed at the interfaces between the source/drain regions 62 and the source/drain contacts 96. The metal-semiconductor alloy regions 94 can be silicide regions formed of a metal silicide (e.g., titanium silicide, cobalt silicide, nickel silicide, etc.), germanide regions formed of a metal germanide (e.g. titanium germanide, cobalt germanide, nickel germanide, etc.), silicon-germanide regions formed of both a metal silicide and a metal germanide, or the like. The metal-semiconductor alloy regions 94 can be formed before the material(s) of the source/drain contacts 96 by depositing a metal in the openings for the source/drain contacts 96 and then performing a thermal anneal process. The metal can be any metal capable of reacting with the semiconductor materials (e.g., silicon, silicon-germanium, germanium, etc.) of the source/drain regions 62 to form a low-resistance metal-semiconductor alloy, such as nickel, cobalt, titanium, tantalum, platinum, tungsten, other noble metals, other refractory metals, rare earth metals or their alloys. The metal can be deposited by a deposition process such as ALD, CVD, PVD, or the like. After the thermal anneal process, a cleaning process, such as a wet clean, may be performed to remove any residual metal from the openings for the source/drain contacts 96, such as from surfaces of the metal-semiconductor alloy regions 94. The material(s) of the source/drain contacts 96 can then be formed on the metal-semiconductor alloy regions 94.

An ESL 104 and a third ILD 106 are then formed. In some embodiments, The ESL 104 may include a dielectric material having a high etching selectivity from the etching of the third ILD 106, such as, aluminum oxide, aluminum nitride, silicon oxycarbide, or the like. The third ILD 106 may be formed using flowable CVD, ALD, or the like, and the material may include PSG, BSG, BPSG, USG, or the like, which may be deposited by any suitable method, such as CVD, PECVD, or the like.

Subsequently, gate contacts 108 and source/drain vias 110 are formed to contact the upper gate electrodes 80U and the source/drain contacts 96, respectively. As an example to form the gate contacts 108 and the source/drain vias 110, openings for the gate contacts 108 and the source/drain vias 110 are formed through the third ILD 106 and the ESL 104. The openings may be formed using acceptable photolithography and etching techniques. A liner (not separately illustrated), such as a diffusion barrier layer, an adhesion layer, or the like, and a conductive material are formed in the openings. The liner may include titanium, titanium nitride, tantalum, tantalum nitride, or the like. The conductive material may be cobalt, tungsten, copper, a copper alloy, silver, gold, aluminum, nickel, or the like. A planarization process, such as a CMP, may be performed to remove excess material from the top surface of the third ILD 106. The remaining liner and conductive material form the gate contacts 108 and the source/drain vias 110 in the openings. The gate contacts 108 and the source/drain vias 110 may be formed in distinct processes, or may be formed in the same process. Although shown as being formed in the same cross-section, it should be appreciated that each of the gate contacts 108 and the source/drain vias 110 may be formed in different cross-sections, which may avoid shorting of the contacts.

A front-side interconnect structure 114 is formed on the device layer 112. The front-side interconnect structure 114 includes dielectric layers 116 and layers of conductive features 118 in the dielectric layers 116. The dielectric layers 116 may include low-k dielectric layers formed of low-k dielectric materials. The dielectric layers 116 may further include passivation layers, which are formed of non-low-k and dense dielectric materials such as Undoped Silicate-Glass (USG), silicon oxide, silicon nitride, or the like, or combinations thereof over the low-k dielectric materials. The dielectric layers 116 may also include polymer layers.

The conductive features 118 may include conductive lines and vias, which may be formed using damascene processes. Conductive features 118 may include metal lines and metal vias, which includes diffusion barriers and a copper containing material over the diffusion barriers. There may also be aluminum pads over and electrically connected to the metal lines and vias. In some embodiments, contacts to the lower gate stacks 90L and the lower source/drain regions 62L may be made through a backside of the device layer 112 (e.g., a side opposite to the front-side interconnect structure 114).

Various advantages are achieved. The disclosed embodiments may be utilized to form a stacking transistor structure with improvements to patterning steps between the upper and lower FETs. The stacking transistor includes lower gate dielectrics 78L around lower semiconductor nanostructures (e.g., lower channel regions) and upper gate dielectrics 78U around upper semiconductor nanostructures (e.g., upper channel regions). For example, the upper and lower gate dielectrics 78U and 78L may be deposited simultaneously and then treated separately to include different dopants. A directed self-assembly (DSA) material is used to separately pattern the upper and lower gate dielectrics 78U and 78L in order to apply certain treatments to one and not the other.

In some embodiments, the DSA material is provided or prepared to contain block copolymers comprising a first component chain bonded to a second component chain. The first and second component chains are selected for certain properties. For example, the first component chain may have a lower attraction to hydroxyl groups (e.g., hydrophobic or less hydrophilic), a tendency to align with other first component chains, and a resistance or disinclination to cross-link without presence of a photoinitiator additive. For example, a photoinitiator additive is typically included if it is desirable for the vinyl functional groups of the first component chains to form cross-links. In addition, the second component chain may have a higher attraction to hydroxyl groups (e.g., more hydrophilic), also a tendency to align with other second component chains, and an ability and inclination to cross-link without presence of a photoinitiator additive.

The DSA material may be dispensed over the upper and lower gate dielectrics 78U and 78L, at which point the block copolymers may start to assemble. In particular, the second component chains may adsorb to the gate dielectrics 78, which substantially includes a bottom portion of the lower gate dielectrics 78L disposed along an underlying STI region 32. In addition, the first component chains may extend upward and away from the gate dielectrics 78. As a result, the DSA material may start to separate into two material layers—that is, an upper material layer (e.g., comprising the first component chains) and a lower material layer (e.g., comprising the second component chains). A treatment process which includes a UV curing process is then used to initiate cross-linking through the lower material layer as well as covalent bonding to the lower gate dielectrics 78L. As a result, the upper and lower material layers become further distinct, such as through an increase in etch selectivity. A simple removal process (e.g., a wet etch) may thus be used to remove one of the material layers (e.g., the upper material layer) in order to expose a portion of the underlying gate dielectrics 78 (e.g., the upper gate dielectrics 78U). For example, a dipole dopant process may be performed to tune the upper gate dielectrics 78U for the upper FET. Gate electrodes may then be formed simultaneously or separately for the upper and lower FETs. As a result of using the above-described DSA material as disclosed with the various embodiments, upper and lower patterning steps may be simplified to increase the fabrication yield, reduce the fabrication time and/or costs, and improve the performance and reliability of the stacking transistors.

In an embodiment, a method includes forming a multilayer stack over a substrate, the multilayer stack comprising semiconductor layers, dummy layers, and a dielectric isolation layer; patterning the multilayer stack and the substrate into a fin, the fin comprising lower nanostructures, upper nanostructures, dummy nanostructures, and the dielectric isolation layer disposed between the lower nanostructures and the upper nanostructures; forming a dummy gate structure over the fin; forming a source/drain region adjacent to the fin; removing the dummy gate structure to form a recess laterally adjacent to the fin, the recess comprising a lower recess adjacent to the lower nanostructures and an upper recess adjacent to the upper nanostructures; removing the dummy nanostructures from the fin; forming lower gate dielectrics around the lower nanostructures and upper gate dielectrics around the upper nanostructures; dispensing a directed self-assembly material into the recess; exposing the directed self-assembly material to a selected ambient, after exposing the directed self-assembly material to the selected ambient, polymer molecules of the directed self-assembly material being substantially aligned in the recess; performing a curing process on the directed self-assembly material, wherein after performing the curing process: a lower portion of the directed self-assembly material is cured; and an upper portion of the directed self-assembly material is substantially uncured; performing a first etch process to remove the upper portion of the directed self-assembly material; doping a dipole dopant into the upper gate dielectrics; and forming a gate electrode around the lower nanostructures and the upper nanostructures. In another embodiment, the polymer molecules comprise a first component chain and a second component chain, wherein the first component chain is resistant to cross-linking in the absence of a photoinitiator additive, wherein the second component chain has a tendency to cross-link in the absence of a photoinitiator. In another embodiment, exposing the directed self-assembly material to the selected ambient comprises performing an anneal process. In another embodiment, performing the curing process comprises using ultraviolet light. In another embodiment, performing the curing process comprises increasing an etch selectivity between first component chain and the second component chain. In another embodiment, the first etch process comprises an isotropic etch process. In another embodiment, doping the dipole dopant includes forming a dipole film around the upper gate dielectrics; performing a second etch process to remove the lower portion of the directed self-assembly material; performing an anneal process to drive the dipole dopant from the dipole film into the upper gate dielectrics; and removing the dipole film. In another embodiment, the gate electrode comprises a lower gate electrode around the lower nanostructures and an upper gate electrode around the upper nanostructures.

In an embodiment, a method includes forming a stack of first semiconductor layers and second semiconductor layers over an active region of a semiconductor substrate; patterning the stack and the semiconductor substrate into a semiconductor fin; forming an isolation feature alongside the semiconductor; forming a dummy gate structure over the semiconductor fin and the isolation feature; forming an interlayer dielectric laterally adjacent to the dummy gate structure; removing the dummy gate structure and the first semiconductor layers to form a recess; forming interfacial layers and gate dielectric layers around the second semiconductor layers and over an upper surface of the isolation feature; depositing block copolymers into the recess, at least one of the block copolymers comprising a first component chain bonded to a second component chain; performing an ultraviolet curing process on the block copolymers; performing a wet etch process to remove the first component chains of the block copolymers and to expose an upper gate dielectric layer of the gate dielectric layers; performing a treatment process on the upper gate dielectric layer, the treatment process comprising removing the second component chains; and forming a gate electrode over the gate dielectric layers, the gate electrode comprising a metal layer over the gate dielectric layer, wherein a dielectric constant of the gate dielectric layers is greater than a dielectric constant of the isolation feature. In another embodiment, before performing the ultraviolet curing process the second component chains are adsorbed on the gate dielectric layers, and wherein after performing the ultraviolet curing process the second component chains are bonded to the gate dielectric layers. In another embodiment, after performing the ultraviolet curing process: a lower material layer comprising the second component chains is disposed along a bottom surface of the recess; an upper material layer comprising the first component chains is disposed over the lower material layer; and a post-curing etch selectivity between the first component chains and the second component chains is greater than a pre-curing etch selectivity between the first component chains and the second component chains. In another embodiment, a polydispersity index of the block copolymers is less than or equal to about 1.2. In another embodiment, the treatment process includes forming a dipole film around the upper gate dielectric layer; removing the second component chains; and performing an anneal process to diffuse dopants from the dipole film into the upper gate dielectric layer. In another embodiment, the dipole film comprises lanthanum oxide, and wherein the dopants comprise lanthanum.

In an embodiment, a method includes forming a lower gate dielectric around a lower nanostructure, the lower nanostructure being disposed over a substrate and an isolation region; forming an upper gate dielectric around an upper nanostructure, the upper nanostructure being disposed over the lower nanostructure, a dielectric isolation layer being interposed between the lower nanostructure and the upper nanostructure; depositing a polymer solution over the lower gate dielectric and the upper gate dielectric, the polymer solution comprising block copolymers; performing a treatment on the polymer solution to align the block copolymers into an assembled material, the assembled material comprising a lower material layer and an upper material layer; performing a wet etch to remove the upper material layer to expose the upper gate dielectric; forming a metal oxide layer over the upper gate dielectric; performing an anneal process to diffuse dopants from the metal oxide layer to the upper gate dielectric; and forming a gate electrode over the upper gate dielectric and the lower gate dielectric. In another embodiment, a polymer molecule of the block copolymers comprises a high reactivity component chain and a low reactivity component chain. In another embodiment, upon depositing the polymer solution: the high reactivity component chain adsorbs to a bottom portion of the lower gate dielectric along the isolation region; and the low reactivity component chain extends away from the isolation region and protrudes past the upper nanostructure. In another embodiment, a height is measured from the bottom portion of the lower gate dielectric to a point that is level with a region disposed between the lower nanostructure and the upper nanostructure, and wherein a length of the high reactivity component chain is substantially equal to the height. In another embodiment, the gate electrode is continuous from the upper gate dielectric to the lower gate dielectric, wherein an upper transistor comprises the upper nanostructure, the upper gate dielectric, and the gate electrode, and wherein a lower transistor comprises the lower nanostructure, the lower gate dielectric, and the gate electrode. In another embodiment, the upper transistor is an n-type field-effect transistor, and wherein the lower transistor is a p-type field effect transistor.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A method comprising:
forming a multilayer stack over a substrate, the multilayer stack comprising semiconductor layers, dummy layers, and a dielectric isolation layer;
patterning the multilayer stack and the substrate into a fin, the fin comprising lower nanostructures, upper nanostructures, dummy nanostructures, and the dielectric isolation layer disposed between the lower nanostructures and the upper nanostructures;
forming a dummy gate structure over the fin;
forming a source/drain region adjacent to the fin;
removing the dummy gate structure to form a recess laterally adjacent to the fin, the recess comprising a lower recess adjacent to the lower nanostructures and an upper recess adjacent to the upper nanostructures;
removing the dummy nanostructures from the fin;
forming lower gate dielectrics around the lower nanostructures and upper gate dielectrics around the upper nanostructures;
dispensing a directed self-assembly material into the recess;
exposing the directed self-assembly material to a selected ambient, after exposing the directed self-assembly material to the selected ambient, polymer molecules of the directed self-assembly material being substantially aligned in the recess;
performing a curing process on the directed self-assembly material, wherein after performing the curing process:
a lower portion of the directed self-assembly material is cured; and
an upper portion of the directed self-assembly material is substantially uncured;
performing a first etch process to remove the upper portion of the directed self-assembly material;
doping a dipole dopant into the upper gate dielectrics; and
forming a gate electrode around the lower nanostructures and the upper nanostructures.

2. The method of claim 1, wherein the polymer molecules comprise a first component chain and a second component chain, wherein the first component chain is resistant to cross-linking in the absence of a photoinitiator additive, wherein the second component chain has a tendency to cross-link in the absence of a photoinitiator.

3. The method of claim 1, wherein exposing the directed self-assembly material to the selected ambient comprises performing an anneal process.

4. The method of claim 1, wherein performing the curing process comprises using ultraviolet light.

5. The method of claim 4, wherein performing the curing process comprises increasing an etch selectivity between a first component chain and a second component chain.

6. The method of claim 5, wherein the first etch process comprises an isotropic etch process.

7. The method of claim 1, wherein doping the dipole dopant comprises:
forming a dipole film around the upper gate dielectrics;
performing a second etch process to remove the lower portion of the directed self-assembly material;
performing an anneal process to drive the dipole dopant from the dipole film into the upper gate dielectrics; and
removing the dipole film.

8. The method of claim 1, wherein the gate electrode comprises a lower gate electrode around the lower nanostructures and an upper gate electrode around the upper nanostructures.

9. A method comprising:
forming a stack of first semiconductor layers and second semiconductor layers over an active region of a semiconductor substrate;
patterning the stack and the semiconductor substrate into a semiconductor fin;
forming an isolation feature alongside the semiconductor fin;
forming a dummy gate structure over the semiconductor fin and the isolation feature;
forming an interlayer dielectric laterally adjacent to the dummy gate structure;
removing the dummy gate structure and the first semiconductor layers to form a recess;
forming interfacial layers and gate dielectric layers around the second semiconductor layers and over an upper surface of the isolation feature;
depositing block copolymers into the recess, at least one of the block copolymers comprising a first component chain bonded to a second component chain;
performing an ultraviolet curing process on the block copolymers;
performing a wet etch process to remove the first component chains of the block copolymers and to expose an upper gate dielectric layer of the gate dielectric layers;
performing a treatment process on the upper gate dielectric layer, the treatment process comprising removing the second component chains; and
forming a gate electrode over the gate dielectric layers, the gate electrode comprising a metal layer over the gate dielectric layer, wherein a dielectric constant of the gate dielectric layers is greater than a dielectric constant of the isolation feature.

10. The method of claim 9, wherein before performing the ultraviolet curing process, the second component chains are adsorbed on the gate dielectric layers, and wherein after performing the ultraviolet curing process, the second component chains are bonded to the gate dielectric layers.

11. The method of claim 9, wherein after performing the ultraviolet curing process:
a lower material layer comprising the second component chains is disposed along a bottom surface of the recess;
an upper material layer comprising the first component chains is disposed over the lower material layer; and
a post-curing etch selectivity between the first component chains and the second component chains is greater than a pre-curing etch selectivity between the first component chains and the second component chains.

12. The method of claim 9, wherein a polydispersity index of the block copolymers is less than or equal to about 1.2.

13. The method of claim 9, wherein the treatment process comprises:
forming a dipole film around the upper gate dielectric layer;
removing the second component chains; and
performing an anneal process to diffuse dopants from the dipole film into the upper gate dielectric layer.

14. The method of claim 13, wherein the dipole film comprises lanthanum oxide, and wherein the dopants comprise lanthanum.

15. A method comprising:
forming a lower gate dielectric around a lower nanostructure, the lower nanostructure being disposed over a substrate and an isolation region;
forming an upper gate dielectric around an upper nanostructure, the upper nanostructure being disposed over the lower nanostructure, a dielectric isolation layer being interposed between the lower nanostructure and the upper nanostructure;
depositing a polymer solution over the lower gate dielectric and the upper gate dielectric, the polymer solution comprising block copolymers;
performing a treatment on the polymer solution to align the block copolymers into an assembled material, the assembled material comprising a lower material layer and an upper material layer;
performing a wet etch to remove the upper material layer to expose the upper gate dielectric;
forming a metal oxide layer over the upper gate dielectric;
performing an anneal process to diffuse dopants from the metal oxide layer to the upper gate dielectric; and
forming a gate electrode over the upper gate dielectric and the lower gate dielectric.

16. The method of claim 15, wherein a polymer molecule of the block copolymers comprises a high reactivity component chain and a low reactivity component chain.

17. The method of claim 16, wherein upon depositing the polymer solution:
the high reactivity component chain adsorbs to a bottom portion of the lower gate dielectric along the isolation region; and
the low reactivity component chain extends away from the isolation region and protrudes past the upper nanostructure.

18. The method of claim 17, wherein a height is measured from the bottom portion of the lower gate dielectric to a point that is level with a region disposed between the lower nanostructure and the upper nanostructure, and wherein a length of the high reactivity component chain is substantially equal to the height.

19. The method of claim 15, wherein the gate electrode is continuous from the upper gate dielectric to the lower gate dielectric, wherein an upper transistor comprises the upper nanostructure, the upper gate dielectric, and the gate electrode, and wherein a lower transistor comprises the lower nanostructure, the lower gate dielectric, and the gate electrode.

20. The method of claim 19, wherein the upper transistor is an n-type field-effect transistor, and wherein the lower transistor is a p-type field effect transistor.
